(19) United States
(12) Patent Application Publication
(10) Pub. No.: US 2026/0005175 A1
(43) Pub. Date: Jan. 1, 2026

(54) SEMICONDUCTOR DEVICE AND METHOD FOR MANUFACTURING SEMICONDUCTOR DEVICE

(71) Applicant: Rohm Co., Ltd., Kyoto-shi (JP)

(72) Inventors: Shunya MIKAMI, Kyoto-shi (JP); Katsutoki SHIRAI, Kyoto-shi (JP); Yuji OSUMI, Kyoto-shi (JP)

(21) Appl. No.: 19/296,448

(22) Filed: Aug. 11, 2025

Related U.S. Application Data
(63) Continuation of application No. PCT/JP2024/003873, filed on Feb. 6, 2024.

(30) Foreign Application Priority Data
Feb. 17, 2023 (JP) 2023-023382
Feb. 22, 2023 (JP) 2023-025800

(51) Int. Cl. H01L 23/00

(52) U.S. Cl. CPC H01L 24/13; H01L 24/11; H01L 24/14; H01L 24/73; H01L 2224/1134; H01L 2224/13007; H01L 2224/13019; H01L 2224/14133; H01L 2224/73207

(57) ABSTRACT

A semiconductor device includes a semiconductor element and at least one metal bump. The semiconductor element includes a first electrode. The metal bump is bonded to the first electrode. The metal bump includes a fractured portion spaced apart from the first electrode in a thickness direction of the semiconductor element. As viewed in the thickness direction, a center of the fractured portion is offset from a center of the metal bump. The metal bump includes a large-diameter portion in contact with the first electrode, and a small-diameter portion having a diameter smaller than that of the large-diameter portion. The small-diameter portion is located on a side of the large-diameter portion opposite the first electrode.

### TECHNICAL FIELD

The present disclosure relates to a semiconductor device and a method for manufacturing a semiconductor device.

### BACKGROUND ART

Switching elements are used for current control in various industrial devices and vehicles. JP-A-2019-212930 discloses an example of a conventional switching element. The switching element generates an electromotive force upon interrupting the current, thereby producing energy. Active clamping is a function that uses a switching element to absorb this energy.

### BRIEF DESCRIPTION OF THE DRAWINGS

FIG. 1 is a plan view of a semiconductor device according to a first embodiment of the present disclosure.

FIG. 2 is a plan view of a portion of the semiconductor device according to the first embodiment of the present disclosure.

FIG. 3 is a circuit diagram of a semiconductor element in the semiconductor device according to the first embodiment of the present disclosure.

FIG. 4 is a front view of the semiconductor device according to the first embodiment of the present disclosure.

FIG. 5 is a side view of the semiconductor device according to the first embodiment of the present disclosure.

FIG. 6 is a sectional view taken along line VI-VI in FIG. 2.

FIG. 7 is a sectional view taken along line VII-VII in FIG. 2.

FIG. 8 is a plan view of the semiconductor element in the semiconductor device according to the first embodiment of the present disclosure.

FIG. 9 is a plan view of a metal bump in the semiconductor device according to a first embodiment of the present disclosure.

FIG. 10 is a sectional view taken along line X-X in FIG. 9.

FIG. 11 is a fragmentary sectional view, illustrating a method for manufacturing the semiconductor device according to the first embodiment of the present disclosure.

FIG. 12 is a fragmentary sectional view, illustrating the method for manufacturing the semiconductor device according to the first embodiment of the present disclosure.

FIG. 13 is a fragmentary sectional view, illustrating the method for manufacturing the semiconductor device according to the first embodiment of the present disclosure.

FIG. 14 is a fragmentary sectional view, illustrating the method for manufacturing the semiconductor device according to the first embodiment of the present disclosure.

FIG. 15 is a fragmentary sectional view, illustrating the method for manufacturing the semiconductor device according to the first embodiment of the present disclosure.

FIG. 16 is a fragmentary sectional view, illustrating the method for manufacturing the semiconductor device according to the first embodiment of the present disclosure.

FIG. 17 is a sectional view of a first variation of the metal bump in the semiconductor device according to the first embodiment of the present disclosure.

FIG. 18 is a fragmentary sectional view, illustrating a first variation of the method for manufacturing the semiconductor device according to the first embodiment of the present disclosure.

FIG. 19 is a plan view of a second variation of the metal bump in the semiconductor device according to the first embodiment of the present disclosure.

FIG. 20 is a fragmentary sectional view, illustrating a second variation of the method for manufacturing the semiconductor device according to the first embodiment of the present disclosure.

FIG. 21 is a plan view of a semiconductor device according to a second embodiment of the present disclosure.

FIG. 22 is a plan view of a portion of a semiconductor device according to a third embodiment of the present disclosure.

FIG. 23 is a sectional view taken along line XXIII-XXIII in FIG. 22.

FIG. 24 is a plan view of a portion of a semiconductor device according to a fourth embodiment of the present disclosure.

FIG. 25 is a sectional view taken along line XXV-XXV in FIG. 24.

FIG. 26 is a plan view of a semiconductor device according to a fifth embodiment of the present disclosure.

FIG. 27 is a plan view of a portion of the semiconductor device according to the fifth embodiment of the present disclosure.

FIG. 28 is a circuit diagram of a semiconductor element in the semiconductor device according to a fifth embodiment of the present disclosure.

FIG. 29 is a front view of the semiconductor device according to the fifth embodiment of the present disclosure.

FIG. 30 is a side view of the semiconductor device according to the fifth embodiment of the present disclosure.

FIG. 31 is a sectional view taken along line XXXI-XXXI in FIG. 27.

FIG. 32 is a sectional view taken along line XXXII-XXXII in FIG. 27.

FIG. 33 is a plan view of the semiconductor element in the semiconductor device according to the fifth embodiment of the present disclosure.

FIG. 34 is a partially enlarged sectional view taken along line XXXIV-XXXIV in FIG. 33.

FIG. 35 is a plan view of a first variation of the semiconductor element in the semiconductor device according to the fifth embodiment of the present disclosure.

FIG. 36 shows plan views of variations of a positioning reference portion in the semiconductor device according to the fifth embodiment of the present disclosure.

FIG. 37 is a plan view of a variation of the metal bump in the semiconductor device according to the fifth embodiment of the present disclosure.

FIG. 38 is a plan view of a semiconductor element in a semiconductor device according to a sixth embodiment of the present disclosure.

FIG. 39 is a plan view of a semiconductor element in a semiconductor device according to a seventh embodiment of the present disclosure.

FIG. 40 is a plan view of a semiconductor element in a semiconductor device according to an eighth embodiment of the present disclosure.

FIG. 41 is a plan view of a first variation of the semiconductor element in the semiconductor device according to the eighth embodiment of the present disclosure.

FIG. 42 is a plan view of a semiconductor element in a semiconductor device according to a ninth embodiment of the present disclosure.

FIG. 43 is a plan view of a first variation of the semiconductor element in the semiconductor device according to the ninth embodiment of the present disclosure.

FIG. 44 is a plan view of a portion of a semiconductor device according to a tenth embodiment of the present disclosure.

FIG. 45 is a sectional view taken along line XLV-XLV in FIG. 44.

FIG. 46 is a plan view of a portion of a semiconductor device according to an eleventh embodiment of the present disclosure.

FIG. 47 is a sectional view taken along line XLVII-XLVII in FIG. 46.

### DETAILED DESCRIPTION OF EMBODIMENTS

The following specifically describes preferred embodiments of the present disclosure with reference to the drawings.

In the present disclosure, the terms such as “first”, “second”, “third”, and so on are used merely as labels to identify the items referred to by the terms and are not intended to impose a specific order or sequence on these items.

In the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. The expression

“An object A overlaps with an object B as viewed in a certain direction” implies the situation where, unless otherwise specifically noted, “the object A overlaps with the entirety of the object B”, and “the object A overlaps with a portion of the object B”. In the present disclosure, the expression “A surface A faces in a direction B (or a first side or a second side in the direction B) is not limited, unless otherwise specifically noted, to the situation where the surface A forms an angle of 90° with the direction B but includes the situation where the surface A is inclined relative to the direction B.

### First Embodiment

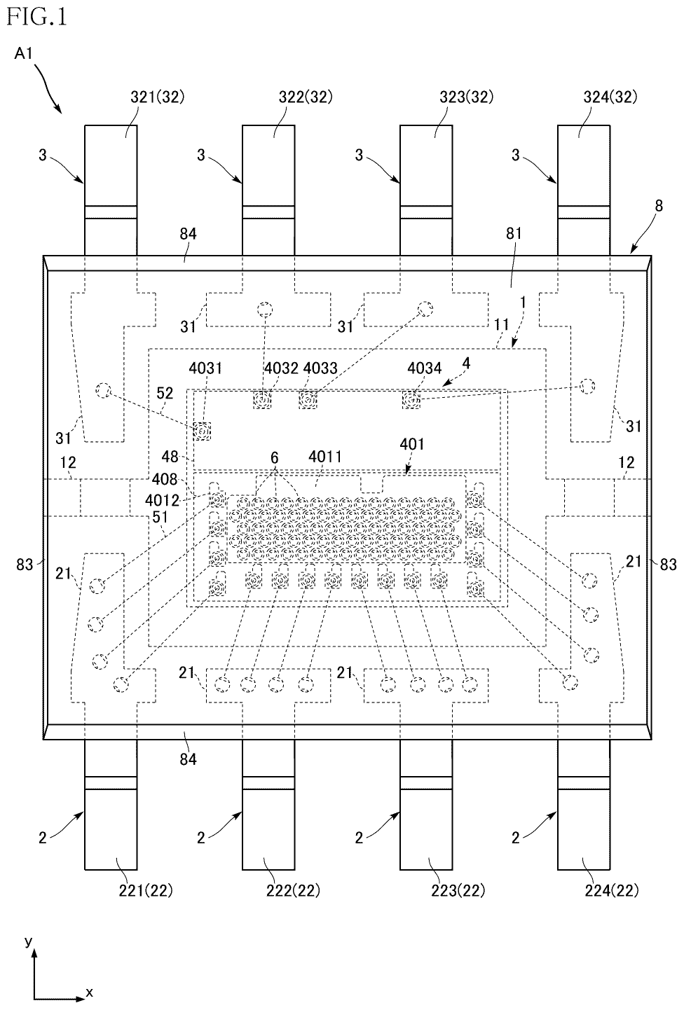

FIGS. 1 to 10 show a semiconductor device A1 according to a first embodiment of the present disclosure. The semiconductor device A1 of the present embodiment includes a first lead 1, a plurality of second leads 2, a plurality of third leads 3, a semiconductor element 4, a plurality of first wires 51, a plurality of second wires 52, a plurality of metal bumps 6, and a sealing resin 8.

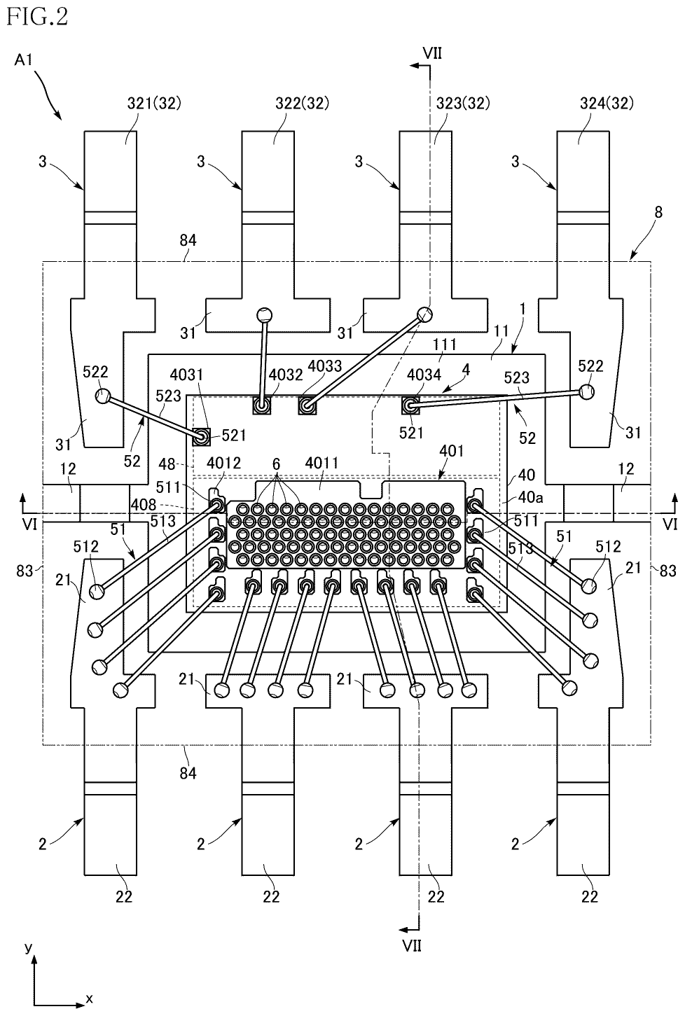

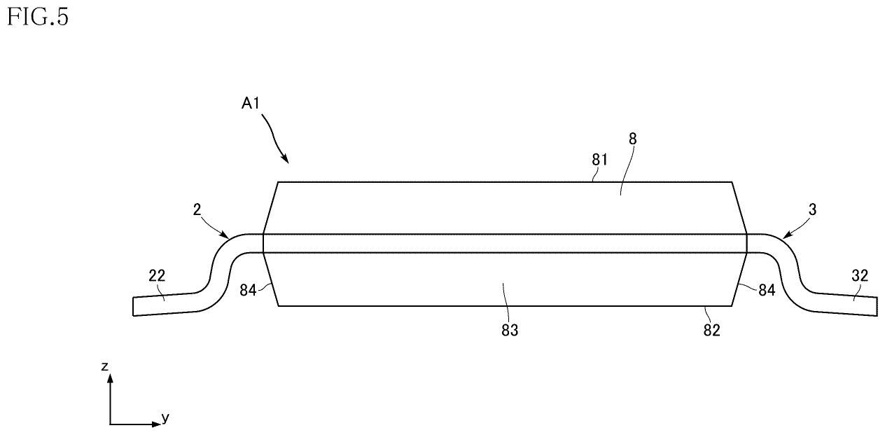

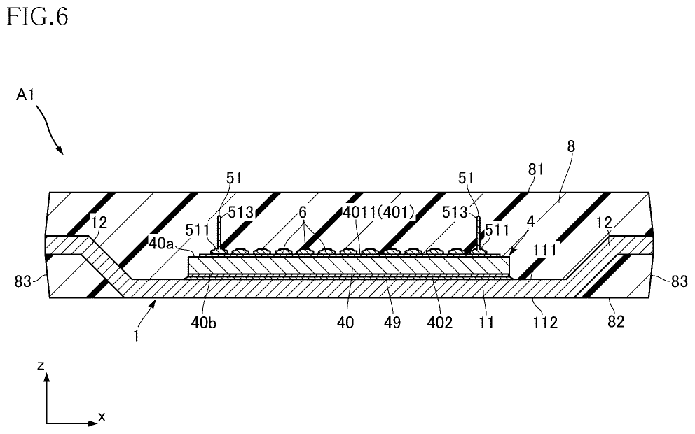

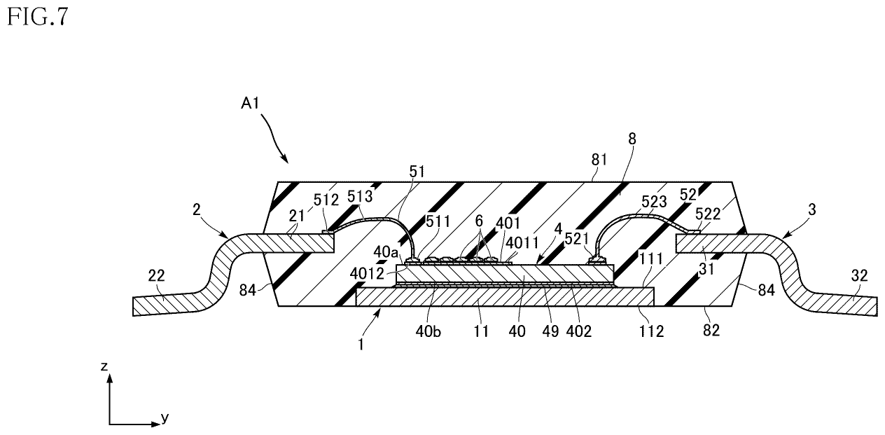

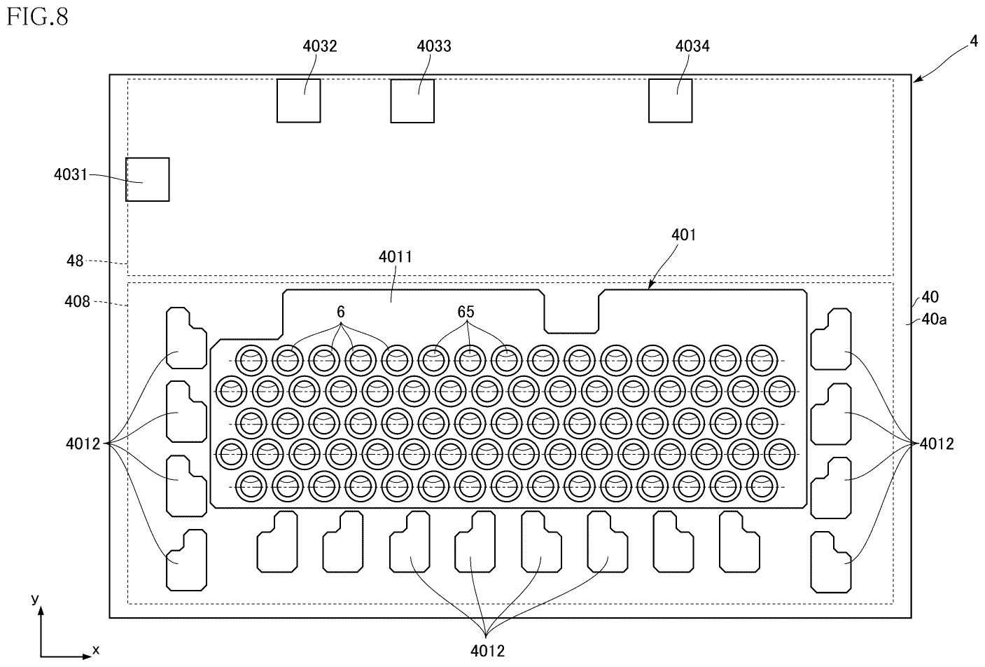

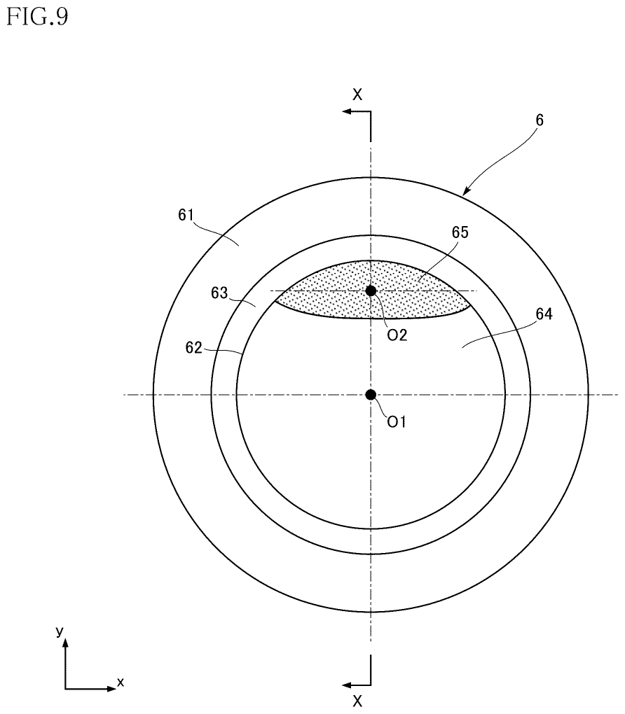

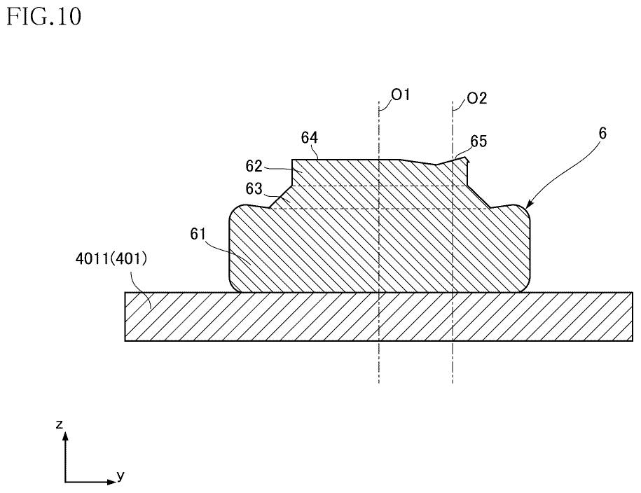

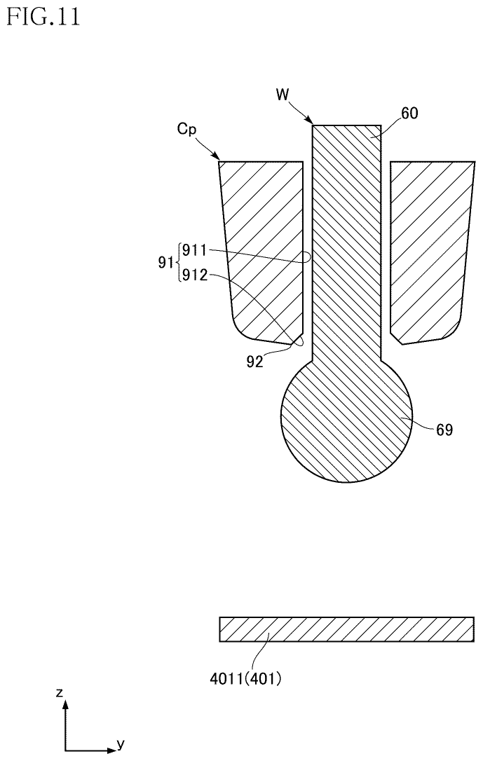

FIG. 1 is a plan view of the semiconductor device A1. FIG. 2 is a plan view of a portion of the semiconductor device A1. FIG. 4 is a front view of the semiconductor device A1. FIG. 5 is a side view of the semiconductor device A1. FIG. 6 is a sectional view taken along line VI-VI in FIG. 2. FIG. 7 is a sectional view taken along line VII-VII in FIG. 2. FIG. 8 is a plan view of a semiconductor element 4. FIG. 9 is a plan view of a metal bump 6. FIG. 10 is a sectional view taken along line X-X in FIG. 9. In these figures, reference is made to three mutually perpendicular directions, as needed. As an example, the z direction corresponds to the “thickness direction” of the present disclosure. The x direction corresponds to the “first direction” of the present disclosure. The y direction corresponds to the “second direction” of the present disclosure.

The shape and size of the semiconductor device A1 are not specifically limited. To give an example of dimensions, the semiconductor device A1 measures about 4 to 7 mm in the x direction, about 4 to 8 mm in the y direction, and about 0.7 to 2.0 mm in the z direction.

### First Lead 1

The first lead 1 supports the semiconductor clement 4 and forms a conduction path to the semiconductor element 4. The material of the first lead 1 is not specifically limited, and suitable materials include metals such as Cu, Ni, and Fe, as well as alloys of such metals. The first lead 1 may be formed with one or more plating layers of metals, such as Ag, Ni, Pd, and Au, on appropriate portions. The thickness of the first lead 1 is not specifically limited and may be about 0.12 to 0.2 mm, for example.

The first lead 1 of the present embodiment includes a die pad portion 11 and two extending portions 12.

The die pad portion 11 supports the semiconductor element 4. The shape of the die pad portion 11 is not specifically limited. In the present embodiment, the die pad portion 11 is rectangular as viewed in the z direction. The die pad portion 11 has a die pad obverse surface 111 and a die pad reverse surface 112. The die pad obverse surface 111 faces in the z direction. The die pad reverse surface 112 faces away from the die pad obverse surface 111 in the thickness direction. In the illustrated example, the die pad obverse surface 111 and the die pad reverse surface 112 are flat.

The two extending portions 12 extend from the opposite sides of the die pad portion 11 in the x direction. In the present embodiment, each extending portion 12 includes a portion extending from the die pad portion 11 in the x direction, a portion extending therefrom at an angle toward the side that the die pad obverse surface 111 faces in the z direction, and a portion extending therefrom in the x direction, thereby generally forming a bent shape.

### Second Leads 2

The second leads 2 are spaced apart from the first lead 1 and form a conduction path to the semiconductor element 4. In the present embodiment, the second leads 2 form a conduction path for the current that is switched on and off by the semiconductor element 4. The second leads 2 are located on a first side in the y direction from the first lead 1. The second leads 2 are spaced apart from each other in the x direction.

The material of the second leads 2 is not specifically limited, and suitable materials include metals such as Cu, Ni, and Fe,, as well as alloys of such metals. The second leads 2 may be formed with one or more plating layers of metals, such as Ag, Ni, Pd, and Au, on appropriate portions. The thickness of the second leads 2 is not specifically limited and may be about 0.12 to 0.2 mm, for example.

The second leads 2 of the present embodiment each include a pad portion 21 and a terminal portion 22.

The pad portion 21 is a site where first wires 51 are bonded. In the present embodiment, the pad portion 21 is located in the z direction from the die pad portion 11, toward the side that the die pad obverse surface 111 faces.

The terminal portion 22 has a band-like shape extending outward in the y direction from the pad portion 21. The terminal portion 22 has a bent shape as viewed in the x direction, with its end positioned at the same (or substantially the same) level as the die pad portion 11 in the z direction. In the illustrated example, the terminal portion 22 is a power terminal.

### Third Leads 3

The third leads 3 are spaced apart from the first lead 1 and form a conduction path to the semiconductor element 4. In the present embodiment, the third leads 3 form a conduction path for the control signal current used to control the semiconductor element 4. The third leads 3 are located on a second side in the y direction from the first lead 1. The third leads 3 are spaced apart from each other in the x direction.

The material of the third leads 3 is not specifically limited, and suitable materials include metals such as Cu, Ni, and Fe, as well as alloys of such metals. The third leads 3 may be formed with one or more plating layers of metals, such as Ag, Ni, Pd, and Au, on appropriate portions.

The thickness of the third leads 3 is not specifically limited and may be about 0.12 to 0.2 mm, for example.

The third leads 3 of the present embodiment each include a pad portion 31 and a terminal portion 32.

The pad portion 31 is a site where a second wire 52 is bonded. In the present embodiment, the pad portion 31 is located in the z direction from the die pad portion 11, toward the side that the die pad obverse surface 111 faces.

The terminal portion 32 has a band-like shape extending outward in the y direction from the pad portion 31. The terminal portion 32 has a bent shape as viewed in the x direction, with its end positioned at the same (or substantially the same) level as the die pad portion 11 in the z direction.

As shown in FIG. 2, the terminal portions 32 of the third leads 3 are individually designated as terminal portions 321, 322, 323, and 324 in the present embodiment. The terminal portion 321 is an output terminal and is electrically connected to a third electrode 4031, which will be described later. The terminal portion 322 is a ground terminal and is electrically connected to a third electrode 4032, which will be described later. The terminal portion 323 is a self-diagnostic output terminal and is electrically connected to a third electrode 4033, which will be described later. The terminal portion 324 is an input terminal and is electrically connected to a third electrode 4034, which will be described later.

### Semiconductor Element 4

The semiconductor clement 4 is the component that performs the electrical function of the semiconductor device A1. The configuration of the semiconductor element 4 is not specifically limited. In the present embodiment, the semiconductor element 4 performs a switching function. As shown in FIGS. 2 and 6 to 8, the semiconductor clement 4 includes an element body 40, a first electrode 401, a second electrode 402, and a plurality of third electrodes 403. The semiconductor clement 4 includes a switching section 408 forming a transistor that performs a switching function, and a control section 48 that controls, monitors, and protects the transistor formed by the switching section 408. The transistor in the control section 48 is a lateral transistor, for example.

The clement body 40 has an element obverse surface 40a and an element reverse surface 40b. The clement obverse surface 40a faces the same side as the die pad obverse surface 111 in the z direction. The element reverse surface 40b faces away from the clement obverse surface 40a in the z direction. The material for the element body 40 is not specifically limited. Suitable materials for the element body 40 include semiconductor materials, such as silicone (Si), silicon carbide (SiC), and gallium nitride (GaN).

The switching section 408 is included in the clement body 40. The switching section 408 forms a transistor structure, which typically is a metal oxide semiconductor field effect transistor (MOSFET) or a metal insulator semiconductor field effect transistor (MISFET). As shown in FIGS. 1, 2 and 8, the switching section 408 is located next to the control section 48 in the y direction, as viewed in the z direction. Note that the arrangements and other details of the switching section 408 and the control section 48 are not specifically limited.

The first electrode 401 is disposed on the element obverse surface 40a of the element body 40. In the illustrated example, the first electrode 401 is located in a region of the element obverse surface 40a that is closer to the second leads 2 in the y direction. The first electrode 401 overlaps with the switching section 408 as viewed in the z direction. In the present embodiment, the first electrode 401 is spaced apart from the control section 48 as viewed in the z direction. In the present embodiment, the first electrode 401 is the source electrode. The material of the first electrode 401 is not specifically limited, and suitable materials include metals and alloys, such as aluminum (Al), Al—Si, and copper (Cu). The first electrode 401 may be a stack of layers of different materials selected from such metals.

As shown in FIG. 8, the first electrode 401 of the present embodiment has a first region 4011 and a plurality of second regions 4012. The first region 4011 and the second regions 4012 are spaced apart from each other as viewed in the z direction. The first region 4011 and the second regions 4012 are not specifically limited in structure. In one example, the metal layer of the first electrode 401 is covered with an insulating layer (not shown). The insulating layer may contain a polyimide resin, for example. The insulating layer has a plurality of openings. Regions of the metal layer exposed through the openings form the first region 4011 and the second regions 4012.

The first region 4011 has a larger area than each second region 4012. The shape of the first region 4011 is not specifically limited. In the illustrated example, the first region 4011 has an elongated shape in the x direction. In the illustrated example, the first region 4011 has a rectangular portion with the x direction as the longitudinal direction, and two portions protruding from the rectangular portion in the y direction.

Each second region 4012 has a smaller area than the first region 4011. The shapes and arrangements of the second regions 4012 are not specifically limited. In the illustrated example, the second regions 4012 include ones that are arranged in the x direction on the first side of the first region 4011 in the y direction, and ones that are arranged in the y direction on opposite sides of the first region 4011 in the x direction.

The second electrode 402 is disposed on the element reverse surface 40b of the element body 40. As viewed in the z direction, the second electrode 402 overlaps with the switching section 408 and the control section 48. In the present embodiment, the second electrode 402 covers the entire surface of the element reverse surface 40b. In the present embodiment, the second electrode 402 is the drain electrode. The material of the second electrode 402 is not specifically limited, and suitable materials include metals and alloys, such as aluminum (Al), Al—Si, and copper (Cu). The second electrode 402 may be a stack of layers of different materials selected from such metals.

The configuration of the control section 48 is not specifically limited. The control section 48 may be a current sensor circuit, a temperature sensor circuit, an overcurrent protection circuit, a heat protection circuit, or an undervoltage protection circuit, for example.

The third electrodes 403 are disposed on the element obverse surface 40a. In the illustrated example, the third electrodes 403 are located in a region of the element obverse surface 40a that is closer to the third lead 3 in the y direction. The third electrodes 403 overlap with the control section 48 as viewed in the z direction. In the present embodiment, the third electrodes 403 are electrically connected mainly to the control section 48. The number of the third electrodes 403 is not specifically limited. For example, the semiconductor element 4 may include a single third electrode 403. In the illustrated example, four third electrodes 403 are included.

In the illustrated example, the four third electrodes 403 include third electrodes 4031, 4032, 4033, and 4034. Each third electrode 4031 is an output electrode. When a short circuit occurs at the load and the output current exceeds an overcurrent threshold, the output current is limited. The third electrode 4032 is the ground electrode. The third electrode 4033 is a self-diagnostic output terminal whose potential changes depending on whether overcurrent or overheating occurs. The third electrode 4034 is an input electrode and connected to an internal pull-down resistor.

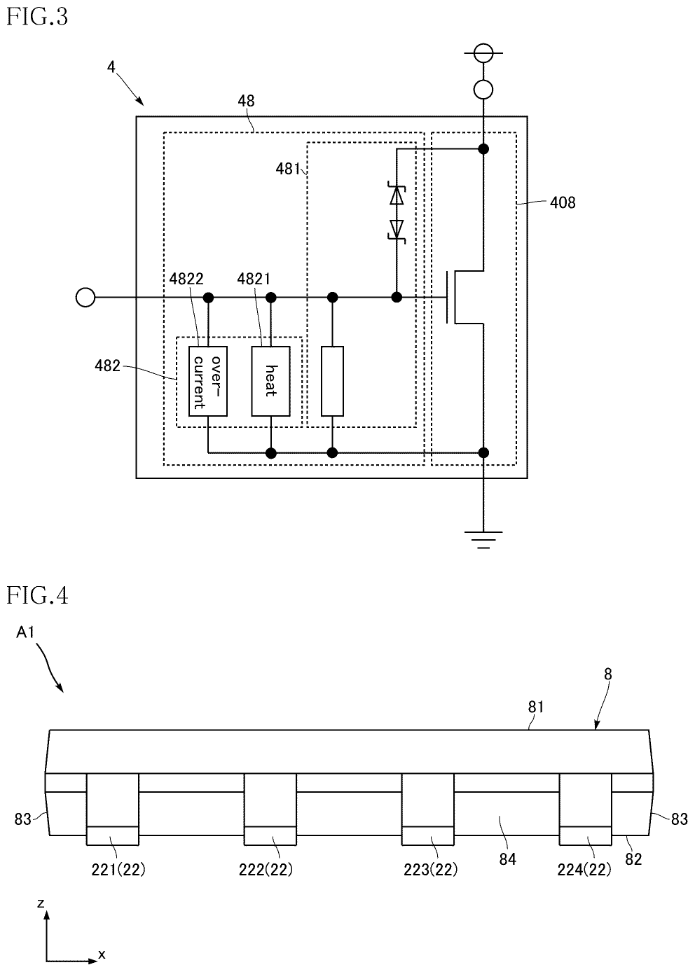

FIG. 3 shows a circuit example of the switching section 408 and the control section 48. The switching section includes a transistor. The control section 48 includes an energy absorption circuit 481 and a protection circuit 482. The energy absorption circuit 481 absorbs electrical energy caused by overvoltage or the like, and includes a Zener diode and a resistor. The protection circuit 482 protects the control section 48 and includes a heat protection section 4821 and an overcurrent protection section 4822.

### First Wires 51

The first wires 51 electrically connect the first electrode 401 of the semiconductor element 4 and the second leads 2. The material of the first wires 51 is not specifically limited, and suitable materials include metals such as gold (Au), copper (Cu), and aluminum (A1). The first wires 51 may contain a metal different from that contained in the first electrode 401. Each first wire 51 includes bonding portions 511 and 512, and a loop portion 513. The structure of the first wires 51 is not specifically limited. In the illustrated example, the first wires 51 are made of a material containing copper (Cu) by using a capillary, for example. In the present embodiment, the first wires 51 carry the current that is switched on and off by the semiconductor element 4.

The semiconductor device according to the present disclosure is not specifically limited to a configuration in which the first wires 51 are bonded to the first electrode 401. For example, instead of the first wires 51, a conductive member made with a metal plate may be bonded to the first electrode 401. In another alternative, the semiconductor element 4 may include an additional electrode that is electrically connected to the first electrode 401 via an internal conduction path, and conductive members, such as the first wires 51, are bonded to the additional electrode.

The bonding portion 511 is electrically connected to the first electrode 401 of the semiconductor element 4 and overlaps with the first electrode 401 as viewed in the z direction. In the present embodiment, the bonding portion 511 is bonded to the first electrode 401 and thus is what is commonly referred to as the first bond.

The bonding portion 512 is bonded to the pad portion 21 of the second lead 2. The bonding portion 512 is what is commonly referred to as the second bond.

The loop portion 513 is a portion between the two bonding portions 511 and 512 and generally has a curved shape, for example.

In the illustrated example, the bonding portions 511 are formed on the second region 4012 of the first electrode 401. Thus, the bonding portions 511 are located along three edges in the outer periphery of the element body 40. The bonding portions 511 are arranged in a line along the outer periphery of the first electrode 401.

### Second Wires 52

The second wires 52 electrically connect the third electrode 403 of the semiconductor clement 4 and the third leads 3. The material of the second wires 52 is not specifically limited, and suitable materials include metals such as gold (Au), copper (Cu), and aluminum (Al). Each second wire 52 includes bonding portions 521 and 522, and a loop portion 523. The structure of the second wires 52 is not specifically limited. In the illustrated example, the second wires 52 are formed by using a capillary, for example.

In the present embodiment, the second wires 52 carry the current of the control signal for controlling the semiconductor element 4. In the example shown in FIG. 2, one of the second wires 52 connects the third electrode 4031 and the pad portion 31 of the third lead 3 having the terminal portion 321. Another second wire 52 connects the third electrode 4032 and the pad portion 31 of the third lead 3 having the terminal portion 322. A yet another second wire 52 connects the third electrode 4033 and the pad portion 31 of the third lead 3 having the terminal portion 323. A yet another second wire 52 connects the third electrode 4034 and the pad portion 31 of the third lead 3 having the terminal portion 324.

The bonding portion 521 is bonded to the second electrode 402 of the semiconductor clement 4. The bonding portion 521 is what is commonly referred to as the first bond.

The bonding portion 523 is bonded to the pad portion 31 of the third lead 3. The bonding portion 522 is what is commonly referred to as the second bond.

The loop portion 523 is a portion between the two bonding portions 521 and 522 and generally has a curved shape, for example.

### Metal Bumps 6

The plurality of metal bumps 6 contain metal and bonded to the first electrode 401. The configuration of the metal bumps 6 is not specifically limited. In the present embodiment, the metal bumps 6 are similar in configuration to the bonding portions 511 of the first wires 51. In other words, each metal bump 6 is formed by using a capillary through a process similar to forming the first wires 51, except that the wire material is cut after the formation of the bonding portion 511. In the present embodiment, the metal bumps 6 contain copper (Cu). The number of metal bumps 6 is not specifically limited.

As shown in FIG. 8, the metal bumps 6 of the present embodiment are located in the first region 4011 of the first electrode 401 and bonded to the first region 4011. The arrangement of metal bumps 6 is not specifically limited. In the illustrated example, the metal bumps 6 are arranged in a plurality of lines in the x direction. The metal bumps 6 in the adjacent lines in the y direction are offset from each other in the x direction. That is, the metal bumps 6 are in a staggered arrangement. Alternatively, the metal bumps 6 may be arranged in a matrix pattern extending in the x and y directions, for example.

As shown in FIGS. 9 and 10, each metal bump 6 has a large-diameter portion 61, a small-diameter portion 62, a first tapered portion 63, a top surface 64, and a fractured portion 65. The large-diameter portion 61 is in contact with the first electrode 401 (the first region 4011). In the illustrated example, the large-diameter portion 61 has a low-profile cylindrical shape (or substantially cylindrical shape). The small-diameter portion 62 is on the side of the large-diameter portion 61 opposite the first electrode 401 (the first region 4011) in the z direction. In the illustrated example, the small-diameter portion 62 has a low-profile cylindrical shape (or substantially cylindrical shape). The small-diameter portion 62 has a diameter smaller than that of the large-diameter portion 61. In the illustrated example, the centers of both the large-diameter portion 61 and the small-diameter portion 62 coincide with the center O1 of the metal bump 6.

The first tapered portion 63 is located between the large-diameter portion 61 and the small-diameter portion 62. The first tapered portion 63 decreases in diameter from the large-diameter portion 61 to the small-diameter portion 62 along the z direction. Alternatively, each metal bump 6 of the present disclosure may be without a first tapered portion 63.

The fractured portion 65 is located on the side farther from the first electrode 401 (the first region 4011) in the z direction (on the first side). The fractured portion 65 is a site where the wire material W was cut during the method for manufacturing the semiconductor device A1, which will be described later. The fractured portion has a center O2 that is offset from the center O1 of the metal bumps 6. In the present embodiment, the center O2 is offset from the center O1 in the y direction. In the illustrated example, the entire fractured portion 65 is spaced apart from the center O1 as shown in FIG. 9. As shown in FIG. 8, for all of the metal bumps 6, the center O2 of the fractured portion 65 is offset from the center O1 of the metal bump 6 in the y direction toward the control section 48.

The top surface 64 is located on the first side in the z direction and is adjacent to the fractured portion 65 as viewed in the z direction. The top surface 64 intersects the z direction. In the illustrated example, the top surface 64 is substantially perpendicular to the z direction. As used herein, the phrase “substantially perpendicular to the z direction” indicates that there may be angular deviations attributable, for example, to unavoidable manufacturing tolerances, such as when the top surface 64 is formed by sliding a capillary Cp as described later in the method for manufacturing the semiconductor device A1.

### Scaling Resin 8

The sealing resin 8 covers a portion of each of the first lead 1, the second leads 2, and the third leads 3, and the semiconductor element 4, the first wires 51, the second wires 52, and the metal bumps 6. The sealing resin 8 is made of an insulating resin, such as an epoxy resin mixed with a filler.

The shape of the sealing resin 8 is not specifically limited. In the illustrated example, the sealing resin 8 has a resin obverse surface 81, a resin reverse surface 82, two first resin side surfaces 83, and two second resin side surfaces 84.

The resin obverse surface 81, which may be a flat surface, faces the same side as the die pad obverse surface 111 in the z direction. The resin reverse surface 82, which may be a flat surface, faces away from the resin obverse surface 81 in the z direction.

The two first resin side surfaces 83 are located between the resin obverse surface 81 and the resin reverse surface 82 in the z direction and face in the opposite sides in the x direction. The two second resin side surfaces 84 are located between the resin obverse surface 81 and the resin reverse surface 82 in the z direction and face in the opposite sides in the y direction.

The following describes a method for manufacturing a semiconductor device A1 (a method for forming metal bumps 6 in particular), with reference to FIGS. 11 to 18.

First, a wire material W is fed through a through-hole 91 in a capillary Cp as shown in FIG. 11. Then, a ball 69 is formed at the tip of the wire material W. Note that the constituent material of the wire material W is the constituent material of the metal bumps 6 described above. The wire material W has a main body 60. The main body 60 has a uniform diameter and constitutes most of the wire material W that has been fed. The ball 69 is formed by heating a portion of the wire material W that protrudes from the capillary Cp.

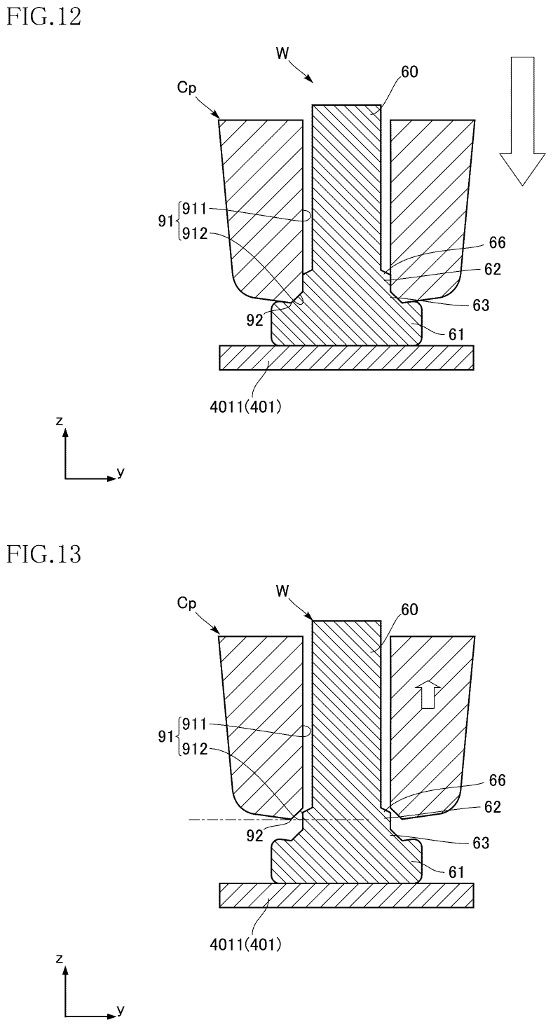

Subsequently, as shown in FIG. 12, the capillary Cp and the wire material W are lowered in the z direction toward the first electrode 401 (the first region 4011). The ball 69 is attached to the first electrode 401 (the first region 4011). At this time, the portion of the ball 69 located between the first electrode 401 (the first region 4011) and the capillary Cp is shaped into a large-diameter portion 61.

In the illustrated example, the through-hole 91 of the capillary has a uniform-diameter portion 911 and a tapered portion 912. The uniform-diameter portion 911 has an inner diameter that is slightly larger than the diameter of the main body 60 of the wire material W. The tapered portion 912 is located near the end of the through-hole 91 and has an inner diameter that gradually increases in a direction away from the uniform-diameter portion 911 (a direction toward the tip portion 92). A portion of the ball 69 that enters the uniform-diameter portion 911 is shaped into the small-diameter portion 62. A portion of the ball 69 that is in contact with the tapered portion 912 is shaped into the first tapered portion 63. In the illustrated example, a second tapered portion 66 is formed between the main body 60 and the small-diameter portion 62.

Subsequently, as shown in FIG. 13, the capillary Cp is moved away from the first electrode 401 (the first region 4011) in the z direction in such a manner that the capillary Cp and the wire material W are allowed to move relative to each other. The relative movement between the capillary Cp and the wire material W is allowed when, for example, the wire material W is not clamped by the capillary Cp. The capillary Cp is moved in the z direction until the tip portion 92 of the capillary Cp overlaps with the small-diameter portion 62 as viewed in a direction perpendicular to the z direction (e.g., as viewed in the x or y direction). In other words, in the illustrated example, the capillary Cp is moved in the z direction until the tip portion 92 of the capillary Cp is positioned beyond the first tapered portion 63 in the z direction.

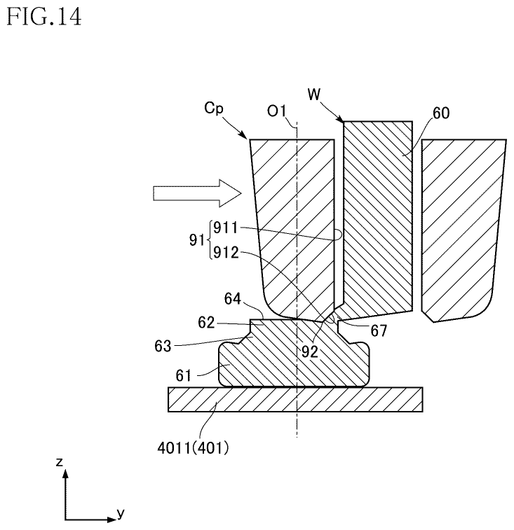

Subsequently, as shown in FIG. 14, the capillary Cp is slid in a sliding direction intersecting the z direction. During the sliding, it is preferable, though not necessary, that the capillary Cp keep clamping the wire material W. In the illustrated example, the capillary Cp is slid until the tip portion 92 of the capillary Cp moves past the center O1. As the capillary Cp slides, the wire material W undergoes shear deformation. As a result, a constricted portion 67 forms in the wire material W. The portion of the wire material W over which the tip portion 92 of the capillary Cp slides forms the top surface 64. The sliding direction can be any direction as long as it causes the formation of the constricted portion 67 in the wire material W. In the illustrated example, the sliding direction is the y direction and thus is perpendicular to the z direction.

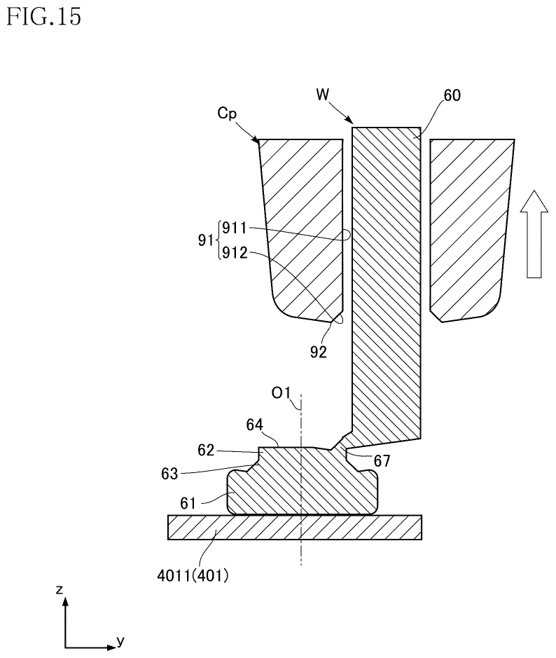

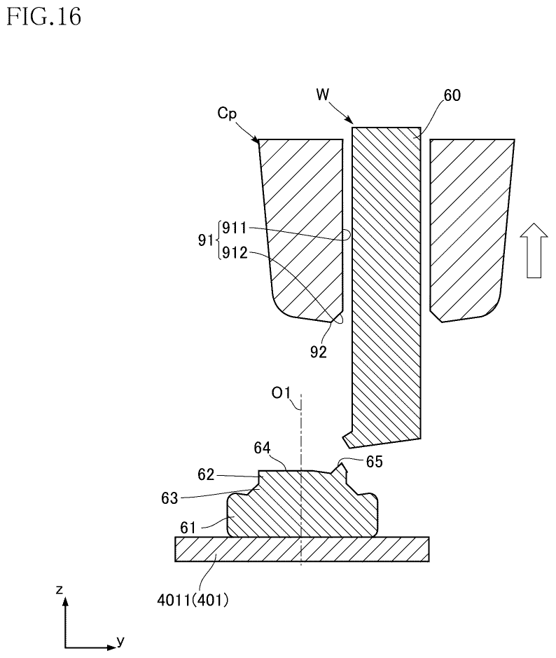

Subsequently, as shown in FIG. 15, the capillary Cp is moved away from the first electrode 401 (the first region 4011) in the z direction (moved toward the first side) in such a manner that the wire material W is allowed to move relative to the capillary Cp.

Subsequently, while the relative movement between the capillary Cp and the wire material W is prevented by the capillary Cp clamping the wire material W, the capillary Cp is moved toward the first side in the z direction as shown in FIG. 16. This causes the wire material W to fracture at the constricted portion 67, forming a metal bump 6. The fractured surface of the constricted portion 67 forms the fractured portion 65.

Thereafter, the steps shown in FIGS. 11 to 16 are repeated to form a plurality of metal bumps 6. In the example shown in FIG. 8, the plurality of metal bumps 6 are sequentially formed, starting from the line farthest from the control section 48 in the y direction. More specifically, when the lines are sequentially numbered from the first, the second . . . and the fifth line, starting with the line farthest from the control section 48, the metal bumps 6 of the first line are formed first, followed by the second line, and so on, until the fifth line is completed. Forming the metal bumps 6 in this order ensures that no metal bump 6 is present in the direction in which the capillary Cp is moved in the process of forming the metal bump 6 as shown in FIG. 14.

The following describes effects of the semiconductor device A1.

According to the present embodiment, the center O2 of the fractured portion 65 is offset from the center O1 of the metal bumps 6 as shown in FIGS. 9 and 10. This is achieved by sliding the capillary Cp to form the constricted portion 67 as shown in FIG. 14 and by inducing a fractur in the wire material W at the constricted portion 67 to form the fractured portion 65 as shown in FIG. 16. The constricted portion 67 has a smaller cross-sectional area and thus is fractured with less force as shown in FIG. 16. This prevents the metal bump 6 from forming an unexpectedly distorted shape. In addition, the force required to fracture the wire material W does not weaken the bond between the metal bump 6 and the first electrode 401. Thus, the metal bumps 6 are formed in a desired shape and reliably bonded to the first electrode 401, allowing active clamping to function more effectively.

In the illustrated example, the entire fractured portion 65 is spaced apart from the center O1 as shown in FIG. 9. This is achieved by sliding the capillary Cp until the entire tip portion 92 of the capillary Cp is away from the center O1 as shown in FIG. 14. This also ensures that the constricted portion 67 has a smaller cross-sectional area. In the process of inducing a fracture in the wire material W as shown in FIG. 16, the portion of the wire material W to be formed into a metal bumps 6 receives a force at a location significantly offset in the y direction. This more reliably prevents weakening of the bond between the metal bump 6 and the first electrode 401.

In the process of sliding the capillary Cp shown in FIG. 14, the tip portion 92 crosses the small-diameter portion 62. In contrast to this process, if the tip portion 92 is moved across the large-diameter portion 61, the wire material W is subjected to a greater shear force. Such a situation could reduce the bonding strength between the portion of the wire material W that forms a metal bump 6 and the first electrode 401. According to the present embodiment, however, the shear force acting on the wire material W is reduced by sliding the capillary Cp. In the case where the wire material W has a first tapered portion 63, the process of moving the capillary Cp shown in FIG. 13 preferably ensures that the tip portion 92 of the capillary Cp is moved to a position beyond the first tapered portion 63.

As shown in FIG. 10, the top surface 64 is substantially perpendicular to the z direction. This is achieved by moving the capillary Cp in a direction perpendicular to the z direction in the process of sliding the capillary Cp shown in FIG. 14. Sliding the capillary Cp in this manner ensures the repeatability of forming metal bumps 6 in a desired shape.

In the process of forming the metal bumps 6, the capillary Cp is moved in a direction where no metal bumps 6 are present as shown in FIG. 8. This ensures that the capillary Cp can slide without interfering with the metal bumps 6 that have already been formed.

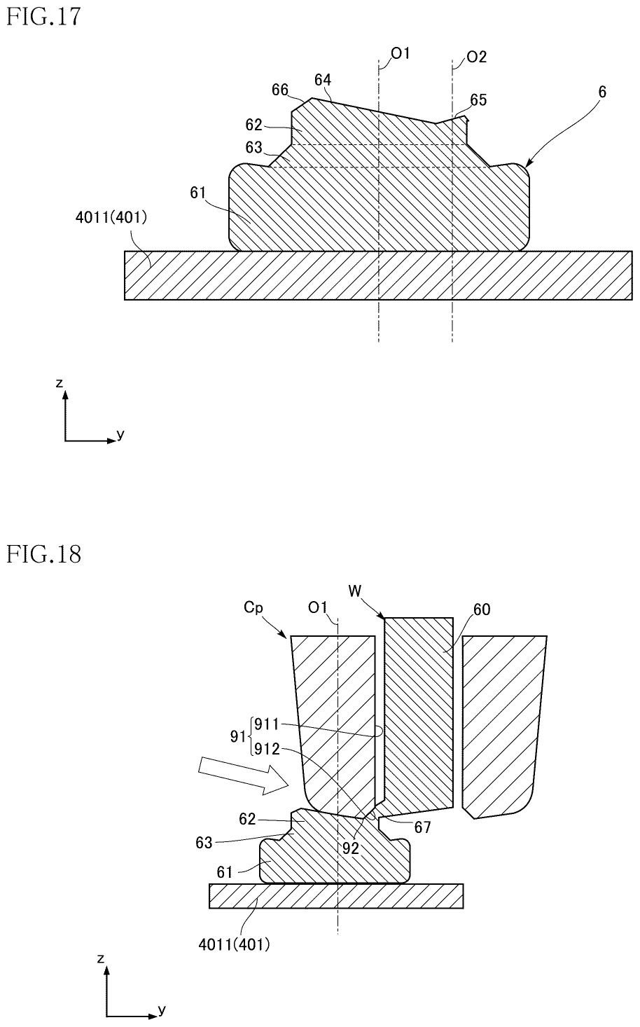

FIGS. 17 to 25 show variations and other embodiments of the present disclosure. In these figures, elements that are identical or similar to those of the embodiment described above are indicated by the same reference numerals. The configurations of elements and components in the embodiments and variations may be combined in any manner, provided that no technical inconsistencies arise.

### First Variation of First Embodiment

FIGS. 17 and 18 show a first variation of the semiconductor device A1 and the method for manufacturing the semiconductor device A1. In this variation, the top surface 64 is slightly inclined relative to the y direction as shown in FIG. 17. Specifically, the top surface 64 is inclined toward the first electrode 401 (the first region 4011) in the z direction as it moves closer to the fractured portion 65 in the y direction.

FIG. 18 shows the process of sliding the capillary Cp of the manufacturing method according to this variation. In this variation, the capillary Cp is moved toward the first electrode 401 (the first region 4011) in the z direction as it slides in the y direction.

This variation enables the active clamping to function more effectively. As can be understood from this variation, the angle of the top surface 64 is not specifically limited. In this variation, during the process of sliding the capillary Cp shown in FIG. 18, the capillary Cp presses the large-diameter portion 61 and the small-diameter portion 62 against the first electrode 401 (the first region 4011). This can increase the bonding strength between the metal bump 6 and the first electrode 401 (the first region 4011).

### Second Variation of First Embodiment

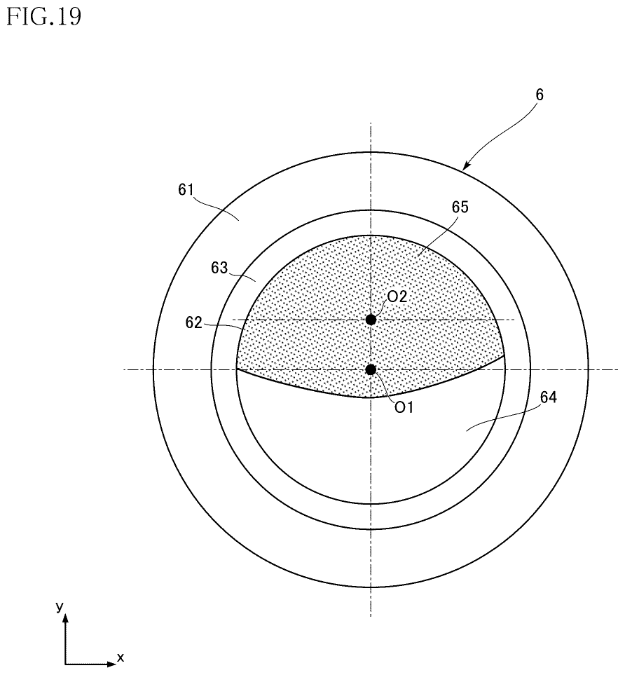

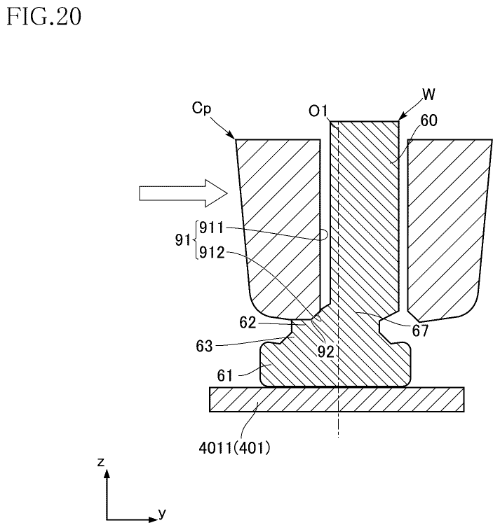

FIGS. 19 and 20 show a second variation of the semiconductor device A1 and the method for manufacturing the semiconductor device A1. As shown in FIG. 19, in this variation, the fractured portion 65 overlaps with the center O1 as viewed in the z direction. As shown in FIG. 20, such metal bumps 6 are formed by sliding the capillary Cp to a position where the tip portion 92 does not fully pass the center O1.

This variation enables the active clamping to function more effectively. As can be understood from this variation, the travel amount of the capillary Cp can be set appropriately.

### Second Embodiment

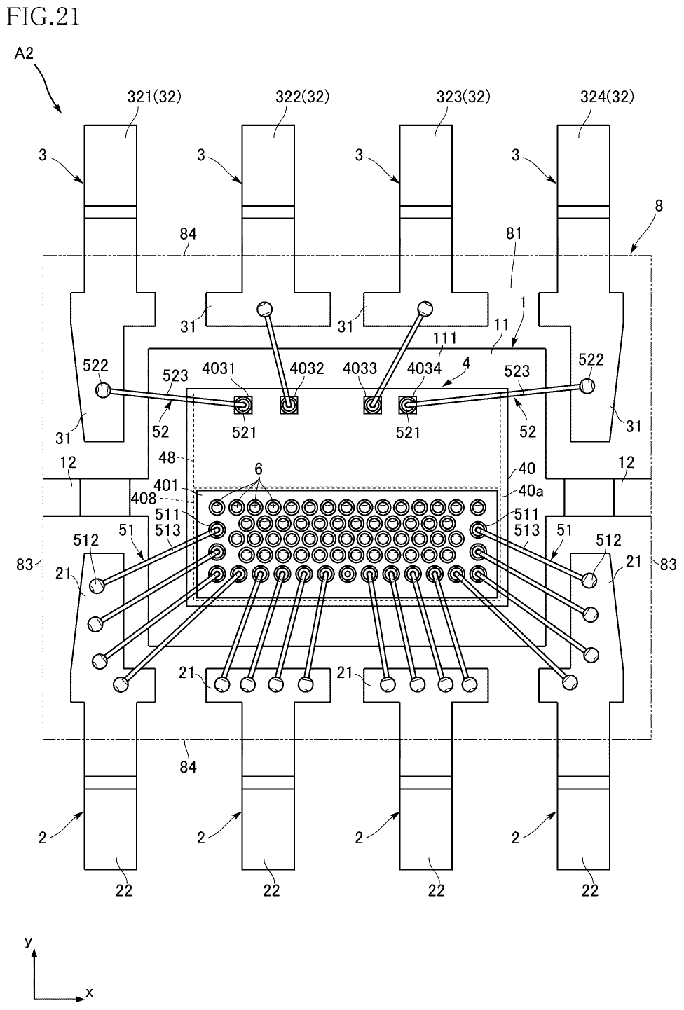

FIG. 21 shows a semiconductor device according to a second embodiment of the present disclosure. The semiconductor device A2 of the present embodiment differs from the above-described embodiment in the configurations of the first electrode 401, the metal bumps 6, and the first wires 51.

In the present embodiment, the metal bumps 6 and the bonding portions 511 of the first wires 51 are all bonded to the same region of the first electrode 401. The first electrode 401 only has a single region.

The bonding portions 511 of the first wires 51 are arranged along both sides of the metal bumps 6 in the x direction and along one side in the y direction.

The present embodiment enables the active clamping to function more effectively. As can be understood from the present embodiment, the metal bumps 6 and the bonding portions 511 of the first wires 51 may be bonded to a single region of the first electrode 401.

### Third Embodiment

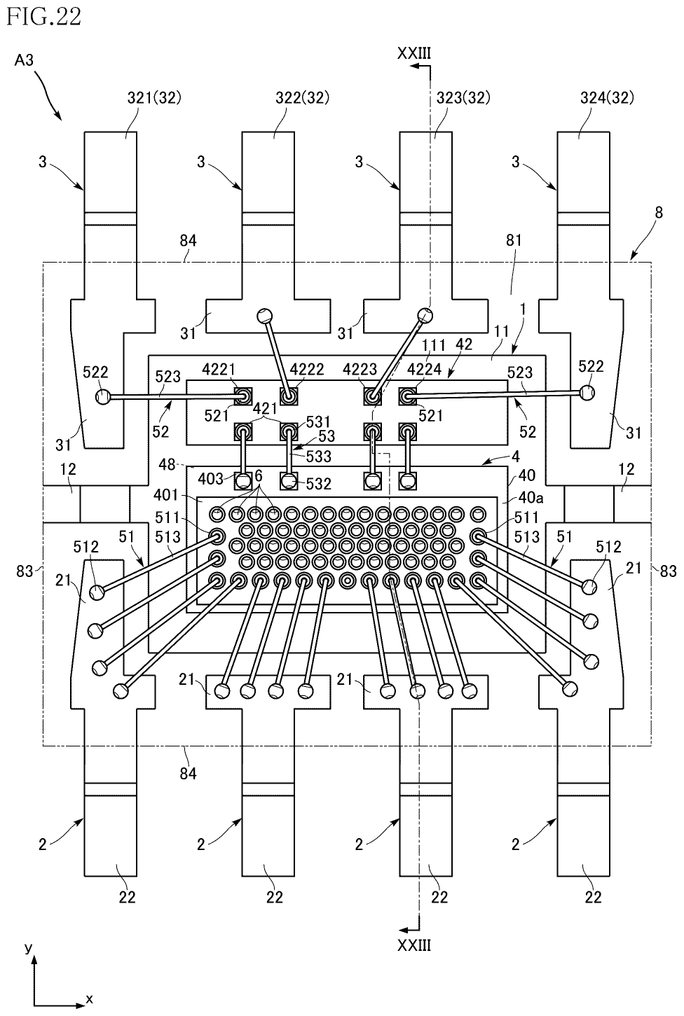

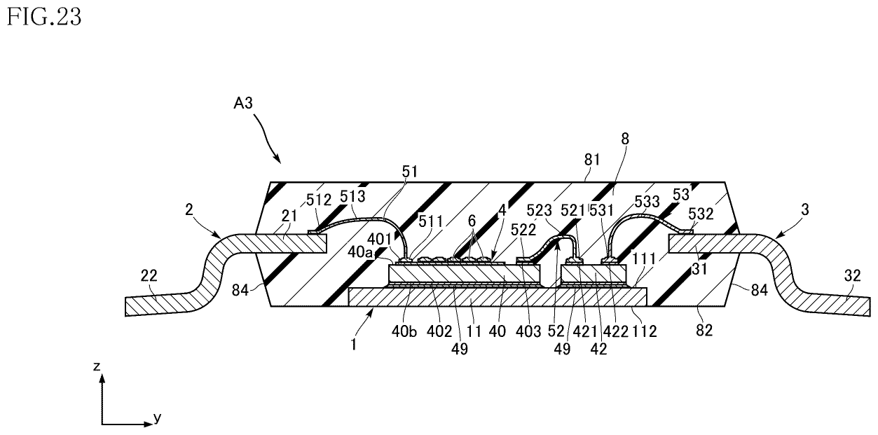

FIGS. 22 and 23 show a semiconductor device according to a third embodiment of the present disclosure. The semiconductor device A3 of the present embodiment differs from the above-described embodiment mainly in the configuration of the semiconductor element 4 and in the addition of a semiconductor element 42 and a plurality of third wires 53.

The semiconductor clement 4 of the present embodiment includes the switching section 408 described in the foregoing embodiment to implement the switching function but does not include the control section 48 described in the foregoing embodiments.

The semiconductor element 42 has the function of controlling, monitoring, and protecting the semiconductor element 4, for example. The semiconductor elements 4 and 42 are both attached to the die pad obverse surface 111 of the die pad portion 11 via a bonding material 49. In the illustrated example, the semiconductor elements 4 and 42 are next to each other in the y direction.

The semiconductor element 42 includes a plurality of electrodes 421 and a plurality of electrodes 422. All of the electrodes 421 and 422 are disposed on the same side in the z direction. In the illustrated example, the electrodes 421 are located closer to the semiconductor element 4 in the y direction, and the electrodes 422 are located closer to the third leads 3 in the y direction. The plurality of electrodes 422 include electrodes 4221, 4222, 4223, and 4224. The electrodes 4221 corresponds to the third electrode 4031 of the semiconductor device A1 of the foregoing embodiment. The electrode 4222 corresponds to the third electrode 4032 of the semiconductor device A1 of the foregoing embodiment. The electrode 4223 corresponds to the third electrode 4033 of the semiconductor device A1 of the foregoing embodiment. The electrode 4224 corresponds to the third electrode 4034 of the semiconductor device A1 of the foregoing embodiment.

In the present embodiment, each of the second wires 52 is connected to an electrode 422 of the semiconductor element 42 and a third lead 3. The bonding portion 521 is bonded to the electrode 422. The bonding portion 522 is bonded to the pad portion 31 of the third lead 3.

The semiconductor device A4 includes a plurality of third wires 53. Each of the third wires 53 is connected to a third electrode 403 of the semiconductor element 4 and an electrode 421 of the semiconductor element 42. Each third wire 53 includes bonding portion 531 and 532 and a loop portion 533, similarly to the second wire 52, for example. The bonding portion 531 is bonded to the third electrode 403. The bonding portion 532 is bonded to the electrode 421.

The present embodiment enables the active clamping to function more effectively. As can be understood from the present embodiment, the configuration of the semiconductor element 4 is not specifically limited. In addition to the semiconductor element 4, one or more other semiconductor elements, such as the semiconductor element 42, may be attached to the die pad portion 11. The functions of the semiconductor elements other than the semiconductor element 4 are not specifically limited.

### Fourth Embodiment

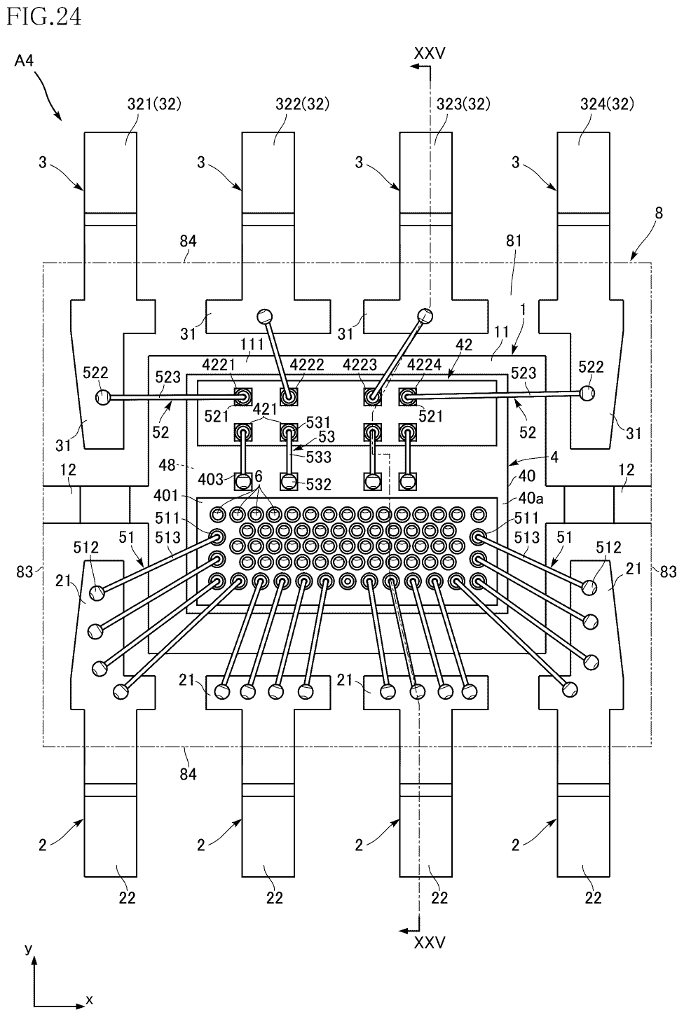

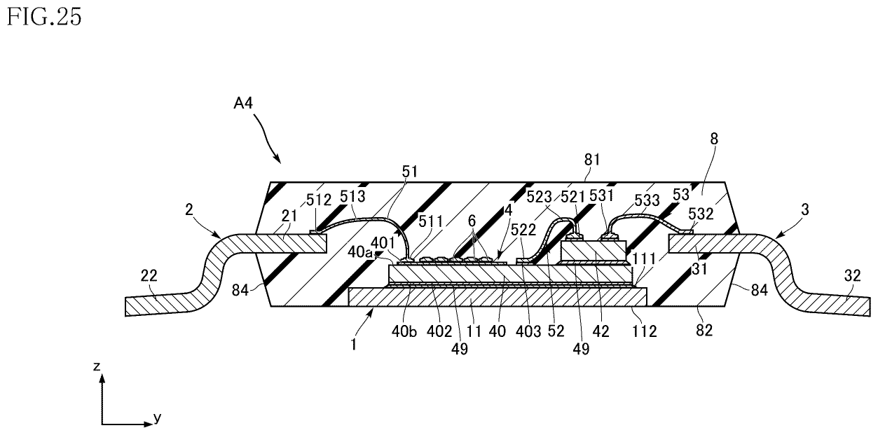

FIGS. 24 and 25 show a semiconductor device according to a fourth embodiment of the present disclosure. Similarly to the semiconductor device A3, the semiconductor device A4 of the present embodiment includes the semiconductor elements 4 and 42.

In the present embodiment, the semiconductor element 42 is mounted on the element obverse surface 40a of the semiconductor element 4. That is, the semiconductor element 42 is on the opposite side of the semiconductor element 4 from the die pad portion 11 in the z direction. The semiconductor elements 4 and 42 are stacked one on top of the other.

The semiconductor element 42 is bonded to the element obverse surface 40a of the semiconductor element 4 via a bonding material 49, for example. In the illustrated example, the semiconductor element 42 is spaced apart from the first electrode 401 in the y direction as viewed in the z direction. In a different example, the semiconductor element 42 may be disposed on the first electrode 401.

In the illustrated example, the first electrode 401 and the semiconductor element 42 both have a rectangle shape elongated in the x direction. The third electrodes 403 are located between the first electrode 401 and the semiconductor element 42 in the y direction and arranged next to each other in the x direction.

The present embodiment enables active clamping to function more effectively. As can be understood from the present embodiment, the configuration and the details of the mounting of the semiconductor element 42 are not specifically limited.

The semiconductor device and the method for manufacturing the semiconductor device of the present disclosure are not limited to those of the foregoing embodiments. Various design changes may be made freely in the specific configurations of the semiconductor device and of the manufacturing methods of the present disclosure.

### Fifth Embodiment

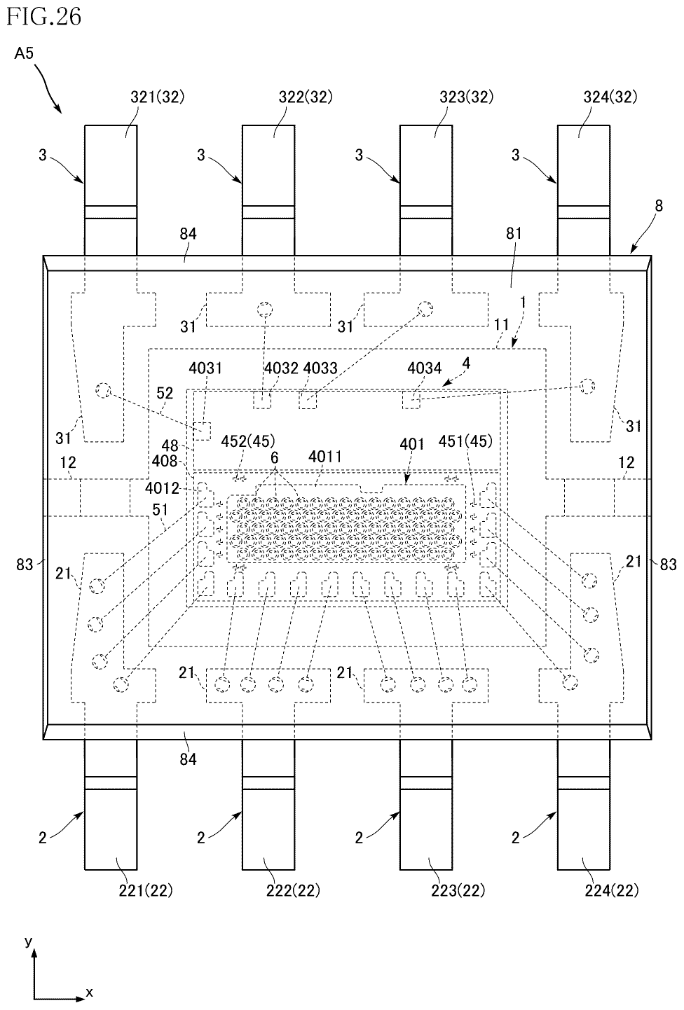

With reference to FIGS. 26 to 34, the following describes a semiconductor device A5 according to a fifth embodiment of the present disclosure. The semiconductor device A5 of the present embodiment includes a first lead 1, a plurality of second leads 2, a plurality of third leads 3, a semiconductor element 4, a plurality of first wires 51, a plurality of second wires 52, a plurality of metal bumps 6, and a sealing resin 8.

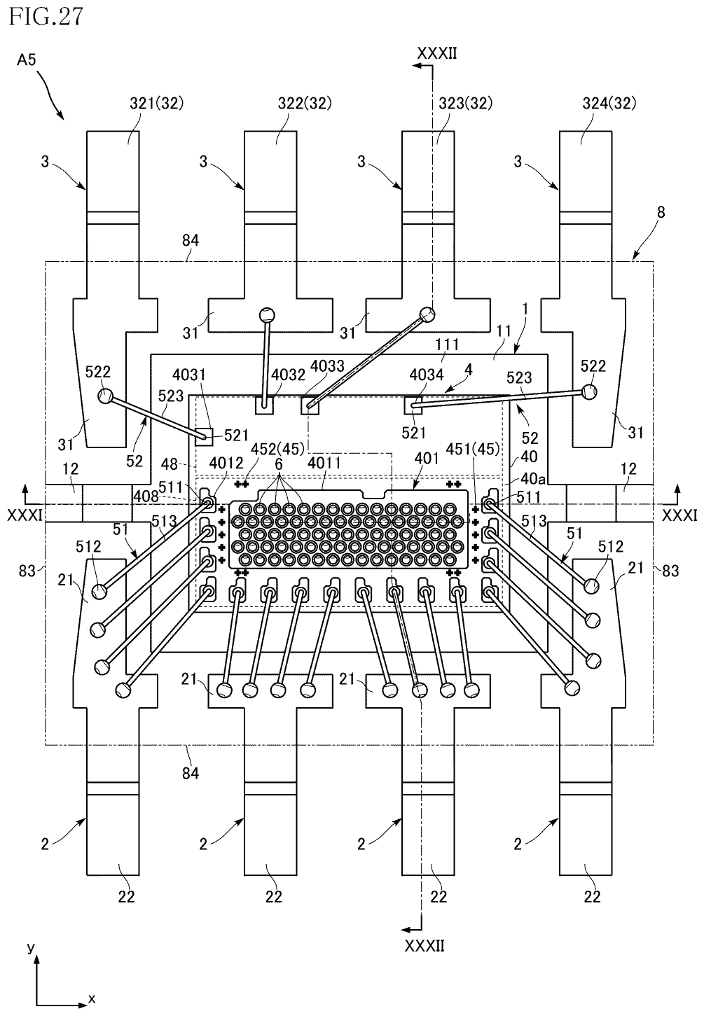

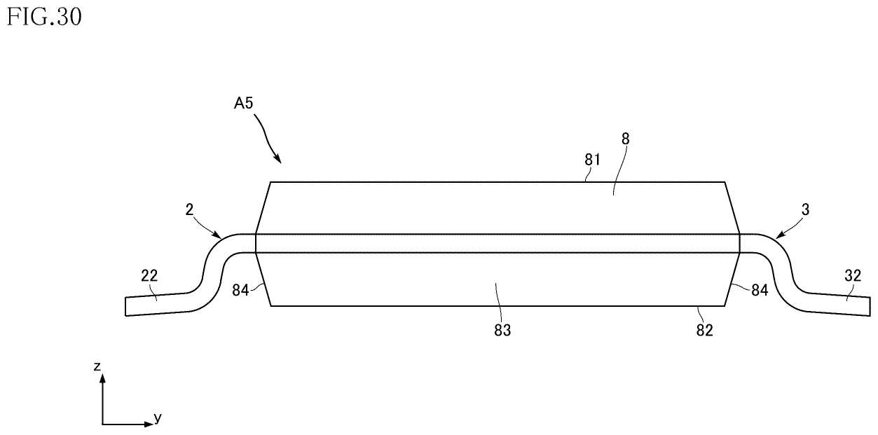

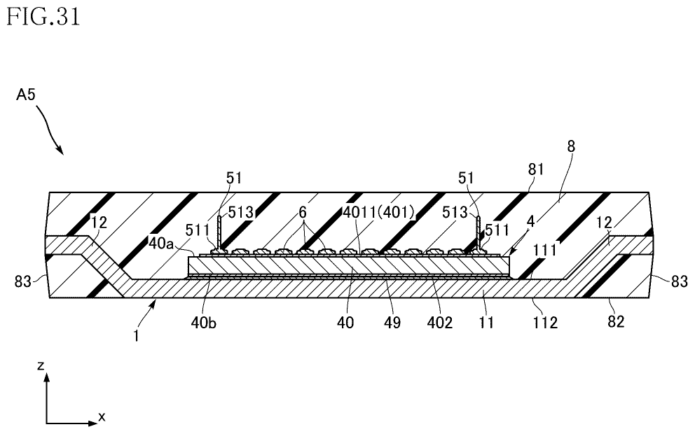

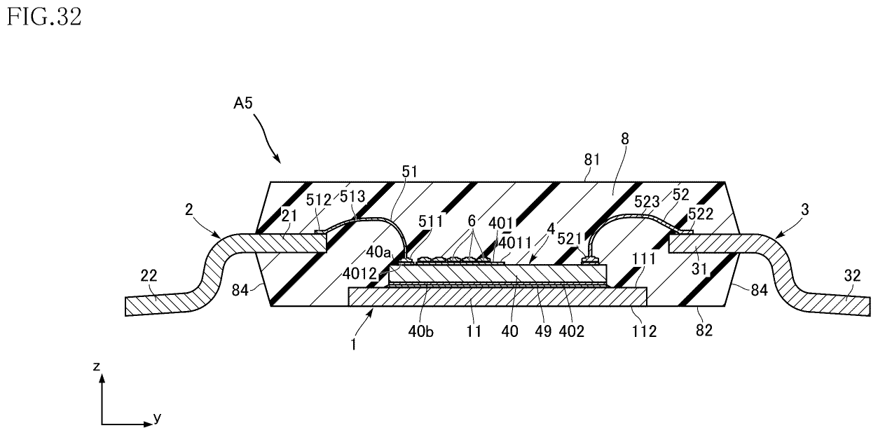

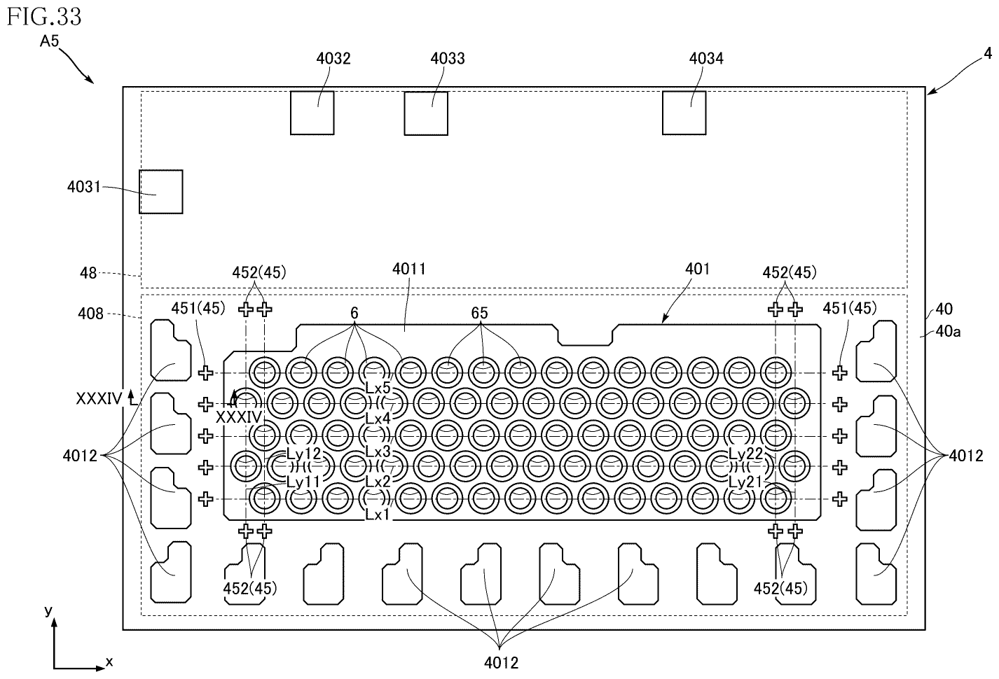

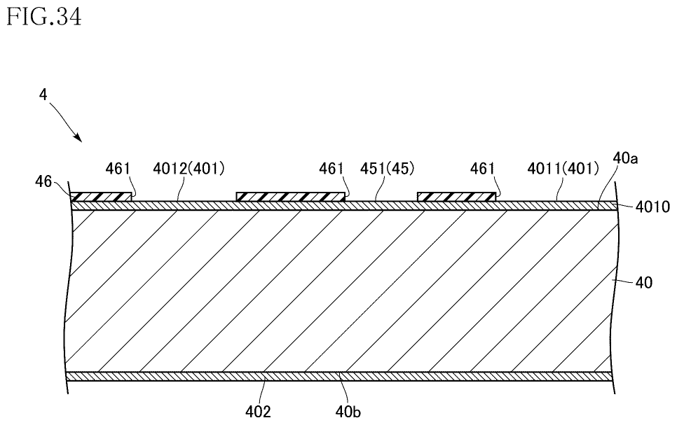

FIG. 26 is a plan view of the semiconductor device A5. FIG. 27 is a plan view of a portion of the semiconductor device A5. FIG. 29 is a front view of the semiconductor device A5. FIG. 30 is a side view of the semiconductor device A5. FIG. 31 is a sectional view taken along line XXXI-XXXI in FIG. 27. FIG. 32 is a sectional view taken along line XXXII-XXXII in FIG. 27. FIG. 33 is a plan view of the semiconductor element 4. FIG. 34 is a partially enlarged sectional view taken along line XXXIV-XXXIV in FIG. 33. The metal bumps 6 of the present embodiment may have the same configuration as the metal bumps 6 of, for example, the first embodiment (see the plan view of FIG. 9 and the sectional view of FIG. 10).

The shape and size of the semiconductor device A5 are not specifically limited. To give an example of dimensions, the semiconductor device A5 measures about 4 to 7 mm in the x direction, about 4 to 8 mm in the y direction, and about 0.7 to 2.0 mm in the z direction.

### First lead 1

The first lead 1 supports the semiconductor element 4 and forms a conduction path to the semiconductor element 4. The material of the first lead 1 is not specifically limited, and suitable materials include metals such as copper (Cu), nickel (Ni), and iron (Fe), as well as alloys of such metals. The first lead 1 may be formed with one or more plating layers of metals, such as silver (Ag), nickel (Ni), palladium (Pd), and gold (Au), on appropriate portions. The thickness of the first lead 1 is not specifically limited and may be about 0.12 to 0.2 mm, for example.

The first lead 1 of the present embodiment includes a die pad portion 11 and two extending portions 12.

The die pad portion 11 supports the semiconductor element 4. The shape of the die pad portion 11 is not specifically limited. In the present embodiment, the die pad portion 11 is rectangular as viewed in the z direction. The die pad portion 11 has a die pad obverse surface 111 and a die pad reverse surface 112. The die pad obverse surface 111 faces in the z direction. The die pad reverse surface 112 faces away from the die pad obverse surface 111 in the thickness direction. In the illustrated example, the die pad obverse surface 111 and the die pad reverse surface 112 are flat.

The two extending portions 12 extend from the opposite sides of the die pad portion 11 in the x direction. In the present embodiment, each extending portion 12 includes a portion extending from the die pad portion 11 in the x direction, a portion extending therefrom at an angle toward the side that the die pad obverse surface 111 faces in the z direction, and a portion extending therefrom in the x direction, thereby generally forming a bent shape.

### Second Leads 2

The second leads 2 are spaced apart from the first lead 1 and form a conduction path to the semiconductor clement 4. In the present embodiment, the second leads 2 form a conduction path for the current that is switched on and off by the semiconductor element 4. The second leads 2 are located on the first side in the y direction from the first lead 1. The second leads 2 are spaced apart from each other in the x direction.

The material of the second leads 2 is not specifically limited, and suitable materials include metals such as copper (Cu), nickel (Ni), and iron (Fe), as well as alloys of such metals. The second leads 2 may be formed with one or more plating layers of metals, such as silver (Ag), nickel (Ni), palladium (Pd), and gold (Au), on appropriate portions. The thickness of the second leads 2 is not specifically limited and may be about 0.12 to 0.2 mm, for example.

The second leads 2 of the present embodiment each include a pad portion 21 and a terminal portion 22.

The pad portion 21 is a site where a first wire 51 is bonded. In the present embodiment, the pad portion 21 is located in the z direction from the die pad portion 11, toward the side that the die pad obverse surface 111 faces.

The terminal portion 22 has a band-like shape extending outward in the y direction from the pad portion 21. The terminal portion 22 has a bent shape as viewed in the x direction, with its end positioned at the same (or substantially the same) level as the die pad portion 11 in the z direction. In the illustrated example, the terminal portion 22 is a power terminal.

### Third Leads 3

The third leads 3 are spaced apart from the first lead 1 and form a conduction path to the semiconductor element 4. In the present embodiment, the third leads 3 form a conduction path for the control signal current used to control the semiconductor clement 4. The third leads 3 are located on the second side in the y direction from the first lead 1. The third leads 3 are spaced apart from each other in the x direction.

The material of the third leads 3 is not specifically limited, and suitable materials include metals such as copper (Cu), nickel (Ni), and iron (Fe), as well as alloys of such metals. The third leads 3 may be formed with one or more plating layers of metals, such as silver (Ag), nickel (Ni), palladium (Pd), and gold (Au), on appropriate portions. The thickness of the third leads 3 is not specifically limited and may be about 0.12 to 0.2 mm, for example.

The third leads 3 of the present embodiment each include a pad portion 31 and a terminal portion 32.

The pad portion 31 is a site where a second wire 52 is bonded. In the present embodiment, the pad portion 31 is located in the z direction from the die pad portion 11, toward the side that the die pad obverse surface 111 faces.

The terminal portion 32 has a band-like shape extending outward in the y direction from the pad portion 31. The terminal portion 32 has a bent shape as viewed in the x direction, with its end positioned at the same (or substantially the same) level as the die pad portion 11 in the z direction.

As shown in FIG. 27, the terminal portions 32 of the plurality of third leads 3 are individually designated as terminal portions 321, 322, 323, and 324 in the present embodiment. The terminal portion 321 is an output terminal and is electrically connected to a third electrode 4031, which will be described later. The terminal portion 322 is a ground terminal and is electrically connected to a third electrode 4032, which will be described later. The terminal portion 323 is a self-diagnostic output terminal and is electrically connected to a third electrode 4033, which will be described later. The terminal portion 324 is an input terminal and is electrically connected to a third electrode 4034, which will be described later.

### Semiconductor Element 4

The semiconductor element 4 is the component that performs the electrical function of the semiconductor device A5. The configuration of the semiconductor element 4 is not specifically limited. In the present embodiment, the semiconductor element 4 performs a switching function. As shown in FIGS. 27 and 31 to 33, the semiconductor element 4 includes an element body 40, a first electrode 401, a second electrode 402, a plurality of third electrodes 403, and a plurality of positioning reference portions 45. The semiconductor element 4 includes a switching section 408 forming a transistor that performs a switching function, and a control section 48 that controls, monitors, and protects the transistor formed by the switching section 408. The transistor in the control section 48 is a lateral transistor, for example.

The element body 40 has an element obverse surface 40a and an element reverse surface 40b. The element obverse surface 40a faces the same side as the die pad obverse surface 111 in the z direction. The element reverse surface 40b faces away from the element obverse surface 40a in the z direction. The material for the element body 40 is not specifically limited. Suitable materials for the element body 40 include such semiconductor materials as silicone (Si), silicon carbide (SiC), and gallium nitride (GaN).

The switching section 408 is included in the element body 40. The switching section 408 forms a transistor structure, which typically is a metal oxide semiconductor field effect transistor (MOSFET) or a metal insulator semiconductor field effect transistor (MISFET). As shown in FIGS. 26, 27 and 33, the switching section 408 is located next to the control section 48 in the y direction, as viewed in the z direction. Note that the arrangements and other details of the switching section 408 and the control section 48 are not specifically limited.

The first electrode 401 is disposed on the element obverse surface 40a of the element body 40. In the illustrated example, the first electrode 401 is located in a region of the element obverse surface 40a that is closer to the second leads 2 in the y direction. The first electrode 401 overlaps with the switching section 408 as viewed in the z direction. In the present embodiment, the first electrode 401 is spaced apart from the control section 48 as viewed in the z direction. In the present embodiment, the first electrode 401 is the source electrode. The material of the first electrode 401 is not specifically limited, and suitable materials include metals and alloys, such as aluminum (Al), Al—Si, and copper (Cu). The first electrode 401 may be a stack of layers of different materials selected from such metals.

As shown in FIG. 33, the first electrode 401 of the present embodiment includes a first region 4011 and a plurality of second regions 4012. The first region 4011 and the second regions 4012 are spaced apart from each other as viewed in the z direction.

The first region 4011 has a larger area than each second region 4012. The shape of the first region 4011 is not specifically limited. In the illustrated example, the first region 4011 has an elongated shape in the x direction. In the illustrated example, the first region 4011 has a rectangular portion with the x direction as the longitudinal direction, and two portions protruding from the rectangular portion in the y direction. The first region 4011 is not limited to a single continuous section. The first region 4011 may instead consist of a plurality of sections spaced apart from each other. For example, the first region 4011 may include a plurality of sections for placing individual metal bumps 6. In such a configuration, the spacing between adjacent sections in the x and y directions may be about 20 μm, for example.

Each second region 4012 has a smaller arca than the first region 4011. The shapes and arrangements of the second regions 4012 are not specifically limited. In the illustrated example, the second regions 4012 include ones arranged in the x direction along one side in the y direction from the first region 4011, and ones arranged in the y direction along both sides of the first region 4011 in the x direction.

The positioning reference portions 45 serve as a positioning reference for the metal bumps 6. As used herein, the phrase “to serve as a positioning reference for the metal bumps 6” describe that the portions contribute to the process of determining the positions for forming the metal bumps 6 during the manufacture of the semiconductor device A5. In an example where the plurality of metal bumps 6 are formed by ball bonding using a capillary as in the manufacturing method described later, the positioning reference portions 45 are used for the initial setting of the capillary. During the initial setting, a camera, for example, is used to capture an image of a region containing the positioning reference portions 45. Then, the camera is moved relative to the positioning reference portions 45 until the reference line determined on the captured image coincides with or intersects a desired positioning reference portion 45, and then that position of the camera is stored into a manufacturing device. The position stored is used as the reference position of the capillary that forms metal bumps 6 in the method for manufacturing the semiconductor device A5. In the actual process of forming the metal bumps 6, the positioning reference portions 45 are analyzed by an image analysis system, which controls the position of the capillary, and used as the positioning reference for the metal bumps 6.

The configuration of the positioning reference portions 45 is not specifically limited. In the illustrated example, the positioning reference portions 45 are separated from the first region 4011. The positioning reference portions 45 are not limited to this configuration of being separated from the first region 4011 and may be connected to the first region 4011. The shape of the positioning reference portions 45 is not specifically limited. In the illustrated example, each positioning reference portion 45 is composed of two mutually intersecting band-shaped portions, one extending in the x direction and the other in the y direction. The size of the positioning reference portions 45 is not specifically limited. In one example, the length of each positioning reference portion 45 may be at least 2 μm and at most 50 μm in both the x and y directions.

The configurations of the first region 4011, the second regions 4012, and the positioning reference portions 45 are not specifically limited. In the present embodiment, the semiconductor clement 4 includes a metal layer 4010 and an insulating film 46 as shown in FIG. 34. The metal layer 4010 contains metal, such as aluminum (Al), deposited on the clement body 40. The metal layer 4010 is electrically connected to the source region of the element body 40. The thickness of the metal layer 4010 is not specifically limited, and may be at least 2 μm and at most 10 μm, for example. The insulating film 46 covers portions of the metal layer 4010. The insulating film 46 may contain a polyimide resin, for example. The thickness of the insulating film 46 is not specifically limited, and may be at least 2 μm and at most 10 μm, for example. The insulating film 46 has a plurality of openings 461. The openings 461 expose portions of the metal layer 4010. The exposed portions of the metal layer 4010 form the first region 4011, the second regions 4012, and the positioning reference portions 45. The positioning reference portions 45 may alternatively be formed by exposing portions of a component other than the metal layer 4010 through the openings 461, by thinning portions of the insulating film 46, or by patterning an additional layer.

The second electrode 402 is disposed on the element reverse surface 40b of the element body 40. As viewed in the z direction, the second electrode 402 overlaps with the switching section 408 and the control section 48. In the present embodiment, the second electrode 402 covers the entire surface of the clement reverse surface 40b. In the present embodiment, the second electrode 402 is the drain electrode. The material of the second electrode 402 is not specifically limited, and suitable materials include metals such as gold (Au), silver (Ag), nickel (Ni), and titanium (Ti) as well as alloys of such metals. The second electrode 402 may be a stack of layers of different materials selected from such metals.

The configuration of the control section 48 is not specifically limited. The control section 48 may be a current sensor circuit, a temperature sensor circuit, an overcurrent protection circuit, a heat protection circuit, or an undervoltage protection circuit, for example.

The third electrodes 403 are disposed on the element obverse surface 40a. In the illustrated example, the third electrodes 403 are located in a region of the element obverse surface 40a that is closer to the third lead 3 in the y direction. The third electrodes 403 overlap with the control section 48 as viewed in the z direction. In the present embodiment, the third electrodes 403 are electrically connected mainly to the control section 48. The number of the third electrodes 403 is not specifically limited. For example, the semiconductor element 4 may include a single third electrode 403. In the illustrated example, four third electrodes 403 are included.

In the illustrated example, the four third electrodes 403 include third electrodes 4031, 4032, 4033, and 4034. Each third electrode 4031 is an output electrode. When a short circuit occurs at the load and the output current exceeds an overcurrent threshold, the output current is limited. The third electrode 4032 is the ground electrode. The third electrode 4033 is a self-diagnostic output terminal whose potential changes depending on whether overcurrent or overheating occurs. The third electrode 4034 is an input electrode and connected to an internal pull-down resistor.

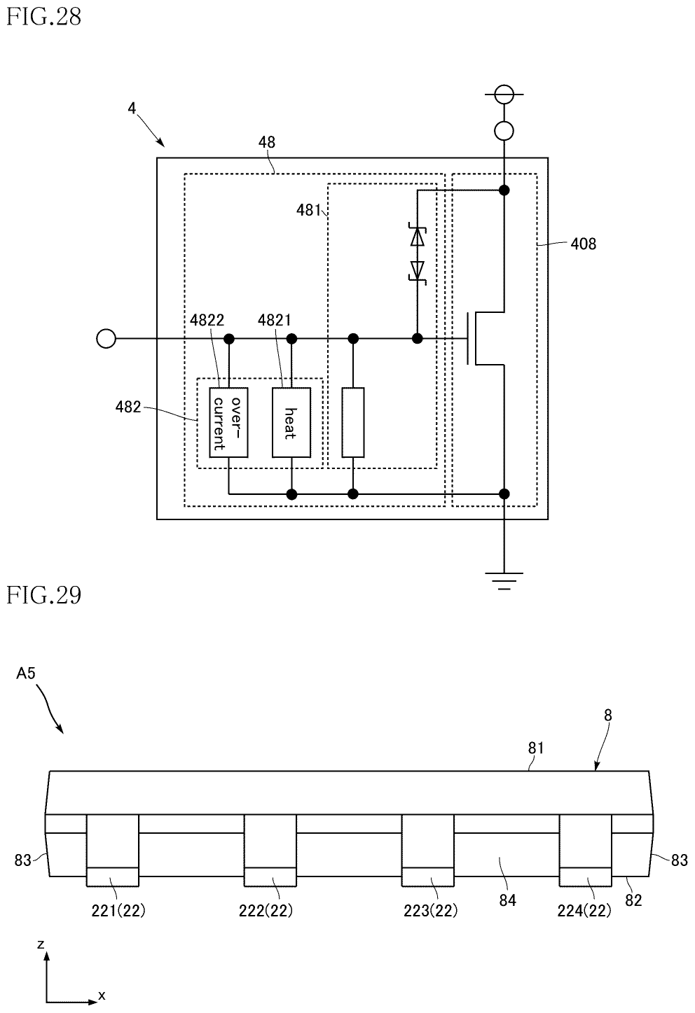

FIG. 28 shows a circuit example of the switching section 408 and the control section 48. The switching section includes a transistor. The control section 48 includes an energy absorption circuit 481 and a protection circuit 482. The energy absorption circuit 481 absorbs electrical energy caused by overvoltage or the like, and includes a Zener diode and a resistor. The protection circuit 482 protects the control section 48 and includes a heat protection section 4821 and an overcurrent protection section 4822.

### First Wires 51

The first wires 51 electrically connect the first electrode 401 of the semiconductor element 4 and the second leads 2. The material of the first wires 51 is not specifically limited, and suitable materials include metals such as gold (Au), copper (Cu), and aluminum (Al). The first wires 51 may contain a metal different from that contained in the first electrode 401. Each second wire 51 includes bonding portions 511 and 512, and a loop portion 513. The structure of the first wires 51 is not specifically limited. In the illustrated example, the first wires 51 are made of a material containing copper (Cu) by using a capillary, for example. In the present embodiment, the first wires 51 carry the current that is switched on and off by the semiconductor element 4.

The semiconductor device according to the present disclosure is not limited to a configuration in which the first wires 51 are bonded to the first electrode 401. For example, instead of the first wires 51, a conductive member made with a metal plate may be bonded to the first electrode 401. In another alternative, the semiconductor element 4 may include an additional electrode that is electrically connected to the first electrode 401 via an internal conduction path, and conductive members, such as the first wires 51, are bonded to the additional electrode.

The bonding portion 511 is electrically connected to the first electrode 401 of the semiconductor element 4 and overlaps with the first electrode 401 as viewed in the z direction. In the present embodiment, the bonding portion 511 is bonded to the first electrode 401 and thus is what is commonly referred to as the first bond.

The bonding portion 512 is bonded to the pad portion 21 of the second lead 2. The bonding portion 512 is what is commonly referred to as the second bond.

The loop portion 513 is a portion between the two bonding portions 511 and 512 and generally has a curved shape.

In the illustrated example, the bonding portions 511 are formed on the second region 4012 of the first electrode 401. Thus, the bonding portions 511 are located along three edges in the outer periphery of the element body 40. The bonding portions 511 are arranged in a line along the outer periphery of the first electrode 401.

### Second Wires 52

The second wires 52 electrically connect the third electrode 403 of the semiconductor clement 4 and the third leads 3. The material of the second wires 52 is not specifically limited, and suitable materials include metals such as gold (Au), copper (Cu), and aluminum (Al). Each second wire 52 includes bonding portions 521 and 522, and a loop portion 523. The structure of the second wires 52 is not specifically limited. In the illustrated example, the second wires 52 are formed by using a capillary, for example.

In the present embodiment, the second wires 52 carry the current of the control signal for controlling the semiconductor element 4. In the example shown in FIG. 27, one of the second wires 52 connects the third electrode 4031 and the pad portion 31 of the third lead 3 having the terminal portion 321. Another second wire 52 connects the third electrode 4032 and the pad portion 31 of the third lead 3 having the terminal portion 322. A yet another second wire 52 connects the third electrode 4033 and the pad portion 31 of the third lead 3 having the terminal portion 323. A yet another second wire 52 connects the third electrode 4034 and the pad portion 31 of the third lead 3 having the terminal portion 324.

The bonding portion 521 is bonded to the second electrode 402 of the semiconductor clement 4. The bonding portion 521 is what is commonly referred to as the second bond.

The bonding portion 522 is bonded to the pad portion 31 of the third lead 3. The bonding portion 522 is what is commonly referred to as the second bond.

The loop portion 523 is a portion between the two bonding portions 521 and 522 and generally has a curved shape.

### Metal Bumps 6

The plurality of metal bumps 6 contain metal and bonded to the first electrode 401. The configuration of the metal bumps 6 is not specifically limited. In the present embodiment, the metal bumps 6 are similar in configuration to the bonding portions 511 of the first wires 51. In other words, each metal bump 6 is formed by using a capillary through a process similar to forming the first wires 51, except that the wire material is cut after the formation of the bonding portion 511. In the present embodiment, the metal bumps 6 contain copper (Cu). The number of metal bumps 6 is not specifically limited.

As shown in FIG. 33, the metal bumps 6 of the present embodiment are located in the first region 4011 of the first electrode 401 and bonded to the first region 4011. The arrangement of metal bumps 6 is not specifically limited. In the illustrated example, the metal bumps 6 are arranged in a plurality of lines in the x direction. In the figure, the metal bumps 6 are arranged in five lines in the x direction. The lines passing through the centers of the metal bums 6 that are arranged in the respective lines are labeled as reference lines Lx1 to Lx5. In the illustrated example, the metal bumps 6 are also arranged in a plurality of lines in the y direction. More specifically, the metal bumps 6 that are arranged along the reference lines Lx1, Lx3, and Lx5 are also arranged in a plurality of lines in the y direction. Similarly, the metal bumps 6 that are arranged along the reference lines Lx2 and Lx4 are also arranged in a plurality of lines in the y direction. In the figure, the lines passing through the centers of the relevant metal bumps 6 arranged in the y direction are labeled as reference lines Ly11, Ly12, Ly21, and Ly22. In the illustrated example, there are a greater number of lines in the y direction than in the x direction. In the illustrated example, the metal bumps 6 are in a staggered arrangement. Alternatively, the metal bumps 6 may be arranged in a matrix pattern extending in the x and y directions, for example.

The plurality of positioning reference portions 45 include a plurality of first positioning reference portions 451 and a plurality of second positioning reference portions 452. The first positioning reference portions 451 serve as a positioning reference for the metal bumps 6 to be arranged in the x direction, among the plurality of metal bumps 6. In the illustrated example, five first positioning reference portions 451 corresponding to the reference lines Lx1 to Lx5 are provided on either side of the first region 4011 in the x direction. In short, the number of the first positioning reference portions 451 on one side of the first region 4011 in the x direction is equal to the number to the lines of metal bumps 6 arranged in the x direction.

The second positioning reference portions 452 serve as the positioning references for the metal bumps 6 to be arranged in the y direction, among the plurality of metal bumps 6. In the illustrated example, four second positioning reference portions 452 corresponding to the reference lines Ly11, Ly12, Ly21, and Ly22 are provided on either side of the first region 4011 in the y direction. In short, the number of the second positioning reference portions 452 on one side of the first region 4011 in the y direction is fewer than the number of lines of metal bumps 6 in the y direction. The second positioning reference portions 452 are placed at the positions corresponding to the outermost metal bumps 6 in the x direction. The outermost metal bumps 6 in the x direction refer to a pair of metal bumps 6 that are farthest apart in the x direction. This configuration is effective for the initial setting of the capillary described above, to determine the positions for forming metal bumps 6 arranged in the x direction. Specifically, the positions for the two outermost metal bumps 6 in the x direction are determined first, followed by the positions of other metal bumps 6 through interpolation.

Depending on the scheme for the initial setting, the first positioning reference portions 451 may be provided only on one side of the first region 4011 in the x direction. Similarly, the second positioning reference portions 452 may be provided only on one side of the first region 4011 in the y direction.

When a wire material W, which will be described later, has a wire diameter of 50 μm, each metal bump 6 formed has a diameter of at least 100 μm and at most 120 μm, for example. In this case, the pitch of the reference lines Lx1 to Lx5 is at least 100 μm and at most 150 μm, although this is just an example and not a limitation. Similarly, the pitch of the reference lines Lyll and Ly 12 and the pitch of the reference lines Ly21 and Ly22 are both at least 50 μm and at most 75 μm, although this is just an example and not a limitation. In the illustrated example, the metal bumps 6 are arranged at a constant pitch in the x direction, but this is not a limitation. In another example, the metal bumps 6 may be arranged at a plurality of different pitches in the x direction. For example, the pitch of the metal bumps 6 along the reference lines Lx1 and Lx2 may be different from the pitch of the metal bumps along the reference lines Lx3, Lx4, and Lx5.

The metal bumps 6 of the present embodiment may be identical in shape to the metal bumps 6 of the first embodiment. Specifically, as shown in FIGS. 9 and 10, each metal bump 6 includes a large-diameter portion 61, a small-diameter portion 62, a first tapered portion 63, a top surface 64, and a fractured portion 65. The large-diameter portion 61 is in contact with the first electrode 401 (the first region 4011). In the illustrated example, the large-diameter portion 61 has a low-profile cylindrical shape (or substantially cylindrical shape). The small-diameter portion 62 is on the side of the large-diameter portion 61 opposite the first electrode 401 (the first region 4011) in the z direction. In the illustrated example, the small-diameter portion 62 has a low-profile cylindrical shape (or substantially cylindrical shape). The small-diameter portion 62 has a diameter smaller than that of the large-diameter portion 61. In the illustrated example, the centers of both the large-diameter portion 61 and the small-diameter portion 62 coincide with the center O1 of the metal bump 6.

The first tapered portion 63 is located between the large-diameter portion 61 and the small-diameter portion 62. The first tapered portion 63 decreases in diameter from the large-diameter portion 61 to the small-diameter portion 62 along the z direction. Alternatively, each metal bump 6 of the present disclosure may be without a first tapered portion 63.

The fractured portion 65 is located on the side farther from the first electrode 401 (the first region 4011) in the z direction (on the first side). The fractured portion 65 is a site where the wire material W was cut during the method for manufacturing the semiconductor device A5, which will be described later. The fractured portion 65 has a center O2 that is offset from the center O1 of the metal bumps 6. In the present embodiment, the center O2 is offset from the center O1 in the y direction. In the illustrated example, the entire fractured portion 65 is spaced apart from the center O1 as shown in FIG. 9. As shown in FIG. 33, for all of the metal bumps 6, the center O2 of the fractured portion 65 is offset from the center O1 of the metal bump 6 in the y direction toward the control section 48.

The top surface 64 is located on the first side in the z direction and is adjacent to the fractured portion 65 as viewed in the z direction. The top surface 64 intersects the z direction. In the illustrated example, the top surface 64 is substantially perpendicular to the z direction. As used herein, the phrase “substantially perpendicular to the z direction” indicates that there may be angular deviations attributable, for example, to unavoidable manufacturing tolerances, such as when the top surface 64 is formed by sliding a capillary Cp as described later in the method for manufacturing the semiconductor device A5.

### Scaling Resin 8

The sealing resin 8 covers a portion of each of the first lead 1, the second leads 2, and the third leads 3, and the semiconductor element 4, the first wires 51, the second wires 52, and the metal bumps 6. The sealing resin 8 is made of an insulating resin, such as an epoxy resin mixed with a filler.

The shape of the sealing resin 8 is not specifically limited. In the illustrated example, the sealing resin 8 has a resin obverse surface 81, a resin reverse surface 82, two first resin side surfaces 83, and two second resin side surfaces 84.

The resin obverse surface 81, which may be a flat surface, faces the same side as the die pad obverse surface 111 in the z direction. The resin reverse surface 82, which may be a flat surface, faces away from the resin obverse surface 81 in the z direction.

The two first resin side surfaces 83 are located between the resin obverse surface 81 and the resin reverse surface 82 in the z direction and face in the opposite sides in the x direction. The two second resin side surfaces 84 are located between the resin obverse surface 81 and the resin reverse surface 82 in the z direction and face in the opposite sides in the y direction.

The following describes a method for manufacturing a semiconductor device A5 (a method for forming metal bumps 6 in particular). The manufacturing method of the present embodiment may be the same as that of the first embodiment. In the following description, reference is made to FIGS. 11 to 16.

First, a wire material W is fed through a through-hole 91 of a capillary Cp as shown in FIG. 11. Then, a ball 69 is formed at the tip of the wire material W. Note that the constituent material of the wire material W is the constituent material of the metal bumps 6 described above. The wire material W has a main body 60. The main body 60 has a uniform diameter and constitutes most of the wire material W that has been fed. The ball 69 is formed by heating a portion of the wire material W that protrudes from the capillary Cp.

Subsequently, as shown in FIG. 12, the capillary Cp and the wire material W are lowered in the z direction toward the first electrode 401 (the first region 4011). The ball 69 is attached to the first electrode 401 (the first region 4011). At this time, the portion of the ball 69 located between the first electrode 401 (the first region 4011) and the capillary Cp is shaped into a large-diameter portion 61.

In the illustrated example, the through-hole 91 of the capillary has a uniform-diameter portion 911 and a tapered portion 912. The uniform-diameter portion 911 has an inner diameter that is slightly larger than the diameter of the main body 60 of the wire material W. The tapered portion 912 is located near the end of the through-hole 91 and has an inner diameter that gradually increases in a direction away from the uniform-diameter portion 911 (a direction toward the tip portion 92). A portion of the ball 69 that enters the uniform-diameter portion 911 is shaped into the small-diameter portion 62. A portion of the ball 69 that is in contact with the tapered portion 912 is shaped into the first tapered portion 63. In the illustrated example, a second tapered portion 66 is formed between the main body 60 and the small-diameter portion 62.

Subsequently, as shown in FIG. 13, the capillary Cp is moved away from the first electrode 401 (the first region 4011) in the z direction in such a manner that the capillary Cp and the wire material W are allowed to move relative to each other. The relative movement between the capillary Cp and the wire material W is allowed when, for example, the wire material W is not clamped by the capillary Cp. The capillary Cp is moved in the z direction until the tip portion 92 of the capillary Cp overlaps with the small-diameter portion 62 as viewed in a direction perpendicular to the z direction (e.g., as viewed in the x or y direction). In other words, in the illustrated example, the capillary Cp is moved in the z direction until the tip portion 92 of the capillary Cp is positioned beyond the first tapered portion 63 in the z direction.

Subsequently, as shown in FIG. 14, the capillary Cp is slid in a sliding direction intersecting the z direction. During the sliding, it is preferable, though not necessary, that the capillary Cp keeps clamping the wire material W. In the illustrated example, the capillary Cp is slid until the tip portion 92 of the capillary Cp moves past the center O1. As the capillary Cp slides, the wire material W undergoes shear deformation. As a result, a constricted portion 67 forms in the wire material W. The portion of the wire material W over which the tip portion 92 of the capillary Cp slides forms the top surface 64. The sliding direction can be any direction as long as it causes the formation of the constricted portion 67 in the wire material W. In the illustrated example, the sliding direction is the y direction and thus is perpendicular to the z direction.

Subsequently, as shown in FIG. 15, the capillary Cp is moved away from the first electrode 401 (the first region 4011) in the z direction (moved toward the first side) in such a manner that the wire material W is allowed to move relative to the capillary Cp.

Subsequently, while the relative movement between the capillary Cp and the wire material W is prevented by the capillary Cp clamping the wire material W, the capillary Cp is moved toward the first side in the z direction as shown in FIG. 16. This causes the wire material W to fracture at the constricted portion 67, forming a metal bump 6. The fractured surface of the constricted portion 67 forms the fractured portion 65.

Thereafter, the steps shown in FIGS. 11 to 16 are repeated to form a plurality of metal bumps 6. For forming the metal bumps 6 as shown in FIG. 33, the capillary Cp sequentially forms the metal bumps 6 at the positions determined in the initial setting. For example, the metal bumps are sequentially formed, starting with the line farthest from the control section 48 in the y direction. That is, metal bumps 6 are formed along the reference line Lx1. Then, metal bumps 6 are formed along the reference line Lx2. Then, metal bumps 6 are formed along the reference line Lx3. Then, metal bumps 6 are formed along the reference line Lx4. Then, metal bumps 6 are formed along the reference line Lx5. The order in which the metal bumps 6 are formed in each line is not specifically limited. In one example, the metal bumps 6 may be sequentially formed along the x direction, beginning with the outermost one. Forming the metal bumps 6 in this order ensures that no metal bump 6 is present in the direction in which the capillary Cp is moved in the process of forming the metal bump 6 as shown in FIG. 14.

The following describes effects of the semiconductor device A5.

According to the present embodiment, the semiconductor clement 4 includes the plurality of positioning reference portions 45. As shown in FIG. 33, the positioning reference portions 45 are used a positioning reference for forming metal bumps 6 at desired locations, thereby improving the positioning accuracy of the metal bumps 6. This makes it possible to form a plurality of metal bumps 6 at a higher density, enabling active clamping to function more effectively.

In the present embodiment, as shown in FIG. 34, the positioning reference portions 45 are formed by portions of the metal layer 4010 exposed through the openings 461 in the insulating film 46. Thus, the positioning reference portions 45 are formed collectively in the process of forming the first region 4011 and the second region 4012. The portions of the metal layer 4010 exposed through the openings 461 are captured in an image with high contrast and thus preferable for accurate position setting.

As shown in FIG. 33, the plurality of positioning reference portions 45 include the first positioning reference portions 451 and the second positioning reference portions 452. This enables accurate setting of the positions where metal bumps 6 are to be formed along the x direction and the y direction. For the process of initial setting described above, the number of second positioning reference portions 452 is less than the number of lines in the y direction. Consequently, the space required for the second positioning reference portions 452 is reduced, allowing for a reduction in the overall size of the semiconductor element 4.

The positioning reference portions 45 are spaced apart from the first region 4011 and the second region 4012. This allows, in images for the initial setting or other settings, the positioning reference portions 45 to be clearly distinguished as discrete features, separate from the first region 4011 or other components. This helps ensure that the initial setting and other tasks are performed more reliably.

According to the present embodiment, the center O2 of the fractured portion 65 is offset from the center O1 of the metal bumps 6 as shown in FIGS. 9 and 10. This is achieved by sliding the capillary Cp to form the constricted portion 67 as shown in FIG. 14 and by inducing a fractur in the wire material W at the constricted portion 67 to form the fractured portion 65 as shown in FIG. 16. The constricted portion 67 has a smaller cross-sectional area and thus is fractured with less force as shown in FIG. 16. This prevents the metal bump 6 from forming an unexpectedly distorted shape. In addition, the force required to fracture the wire material W does not weaken the bond between the metal bump 6 and the first electrode 401. Thus, the metal bumps 6 are formed in a desired shape and reliably bonded to the first electrode 401, allowing active clamping to function more effectively.

In the process of forming the metal bumps 6, the capillary Cp is moved in a direction where no metal bumps 6 are present as shown in FIG. 33. This ensures that the capillary Cp can slide without interfering with the metal bumps 6 that have already been formed.

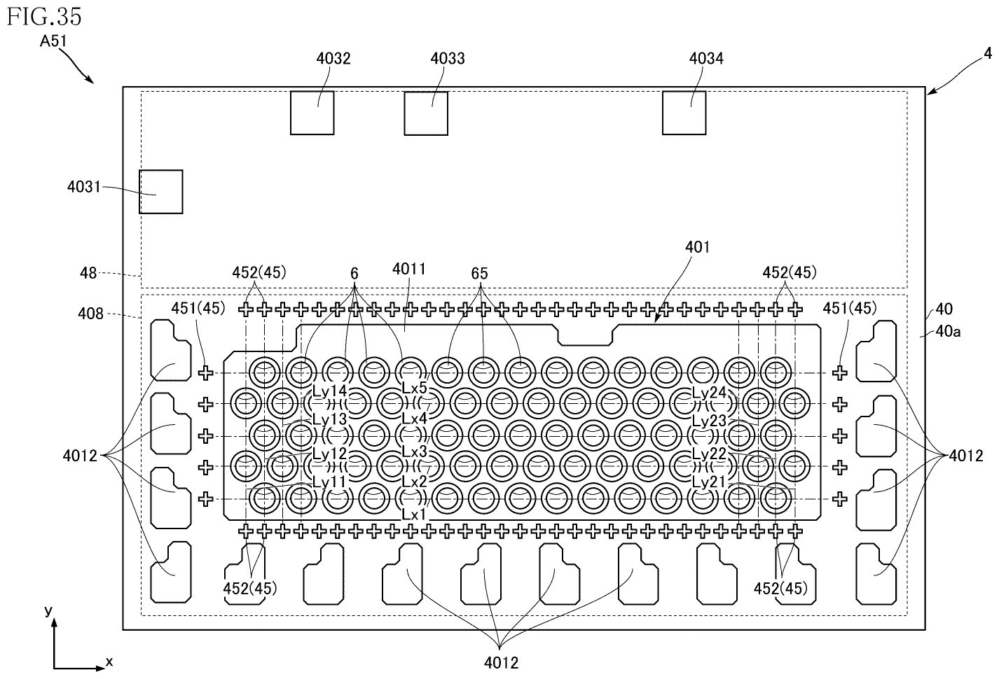

FIGS. 35 to 47 show variations and other embodiments of the present disclosure. In these figures, elements that are identical or similar to those of the embodiment described above are indicated by the same reference numerals. The configurations of elements and components in the embodiments and variations may be combined in any manner, provided that no technical inconsistencies arise.

### First Variation of Fifth Embodiment

FIG. 35 shows a first variation of the semiconductor device A5. In the semiconductor device A51 of this variation, the number of second positioning reference portions 452 on one side of the first region 4011 in the y direction equals the number of lines of metal bumps 6 aligned in the y direction.

This variation enables active clamping to function more effectively. As can be understood from this variation, the number of second positioning reference portions 452 is not specifically limited. Rather, the number can be changed as appropriate according to the specific process for the initial setting, for example.

### Variations of Positioning Reference Portions 45

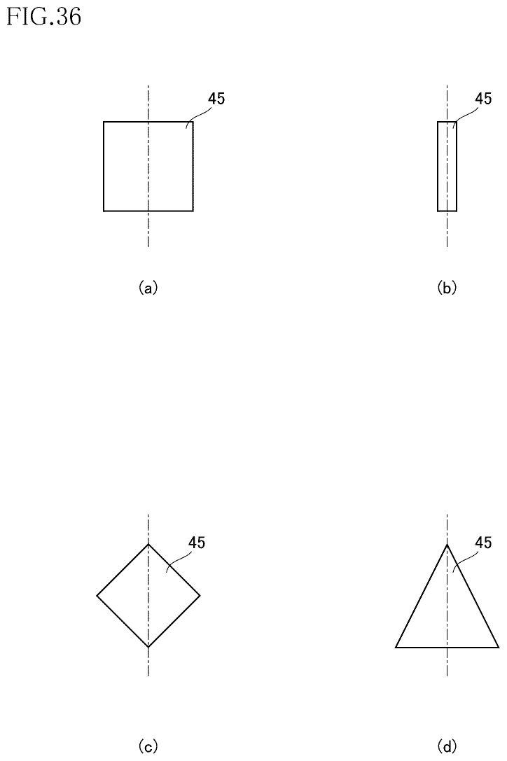

FIG. 36 shows variations of the positioning reference portions 45. The dot-dash line in each of (a) to (d) of the figure corresponds to a relevant one of the reference lines Lx1 to Lx5 and the reference lines Ly11, Ly12, Ly21 and Ly22 shown in FIG. 33. The positioning reference portion 45 shown in (a) of the figure is a quadrilateral, more specifically a square, as viewed in z direction. This positioning reference portion 45 has two edges that are parallel to the reference line, and two edges that are perpendicular to the reference line. The positioning reference portion 45 shown in (b) of the figure has the shape of a strip extending along the reference line. The positioning reference portion 45 shown in (c) of the figure is a quadrilateral (a rhombus) having one diagonal line extending along the reference line and the other perpendicular to the reference line. The positioning reference portion 45 shown in (d) of the figure is a triangle with one vertex intersecting the reference line. For example, the reference line may bisect the vertex angle.

This variation enables active clamping to function more effectively. As can be understood from the variation, the shapes of the positioning reference portions 45 are not specifically limited. Any shape that specifies the reference line can be used.

### Variation of Metal Bumps 6

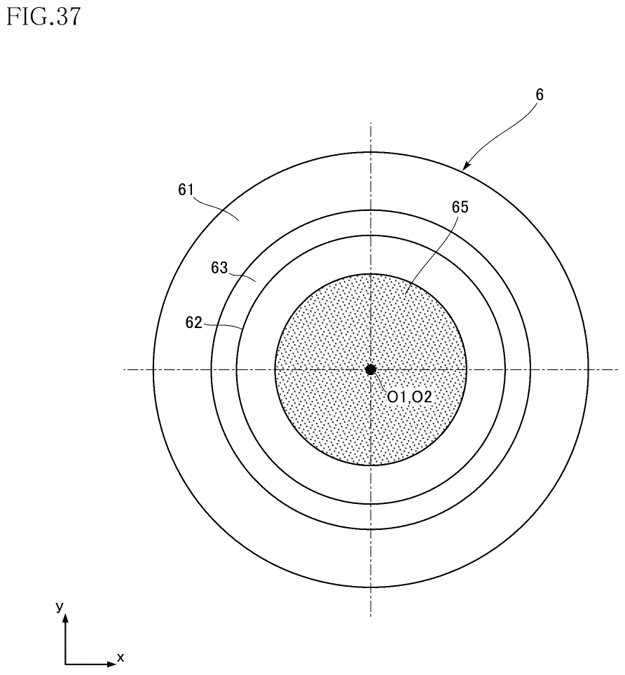

FIG. 37 shows a variation of the metal bumps 6. In this variation, the center O2 of the fractured portion 65 coincides (or substantially coincides) with the center O1 of the metal bump 6. In the process of forming the metal bumps 6 of this variation, the process of moving the capillary Cp in the y direction shown in FIG. 14 is omitted, and the process of inducing a fracture in the wire material W shown in FIG. 16 is performed without it.

This variation enables active clamping to function more effectively. As can be understood from this variation, the shapes and other details of the metal bumps 6 are not specifically limited.

### Sixth Embodiment

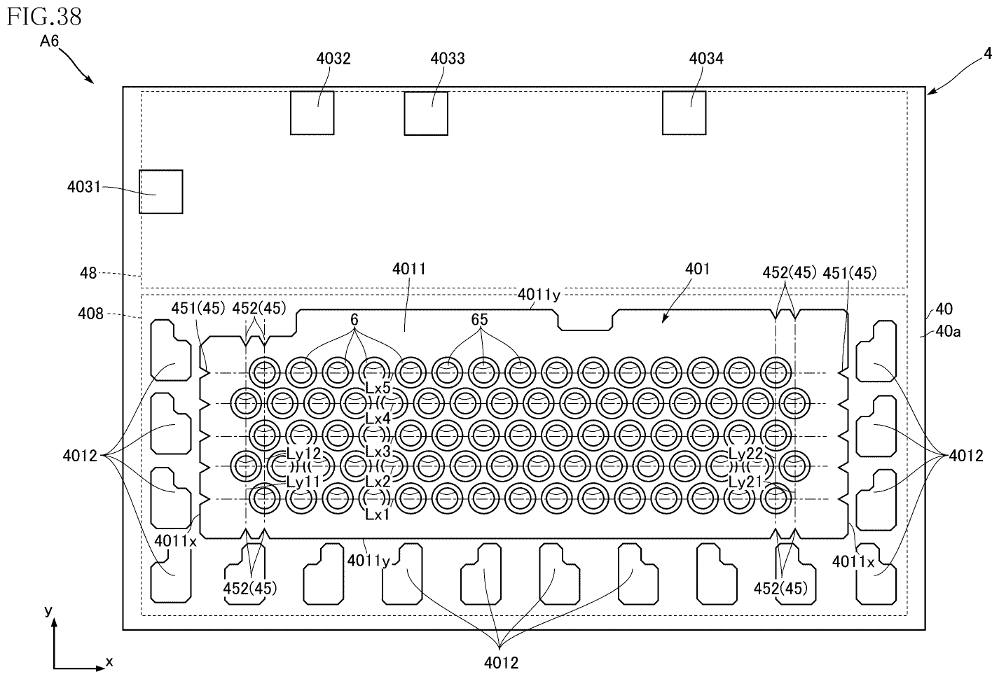

FIG. 38 shows a semiconductor element 4 of a semiconductor device according to a sixth embodiment of the present disclosure. The semiconductor device A6 of the present embodiment includes the semiconductor element 4 having positioning reference portions 45 different from those of the foregoing embodiments. In the present embodiment, the positioning reference portion 45 are not separated from the first region 4011. The first region 4011 has two first edges 4011x and two second edges 4011y. The two first edges 4011x are spaced apart from each other in the x direction. The two second edges 4011y are spaced apart from each other in the y direction.

Each first edge 4011x of the first region 4011 has a plurality of portions that are bent inward as viewed in the z direction. These portions form the first positioning reference portions 451. Each second edge 4011y of the first region 4011 has a plurality of portions that are bent inward as viewed in the z direction. These portions form the second positioning reference portions 452. The positioning reference portions 45 shown in the figure each have a triangular shape with a vertex pointing inward but this is not a limitation. Various shapes, including those shown in FIG. 36, may be used for the positioning reference portions 45.

The present embodiment enables active clamping to function more effectively. In the present embodiment, the positioning reference portions 45 are not separate components but integral portions of the first region 4011 (the first edges 4011x and the second edges 4011y) formed into specific shapes. Compared to the positioning reference portions 45 that are separate from the first region 4011, the positioning reference portions 45 of this embodiment require less space, facilitating a decrease in the size of the semiconductor element 4.

### Seventh Embodiment

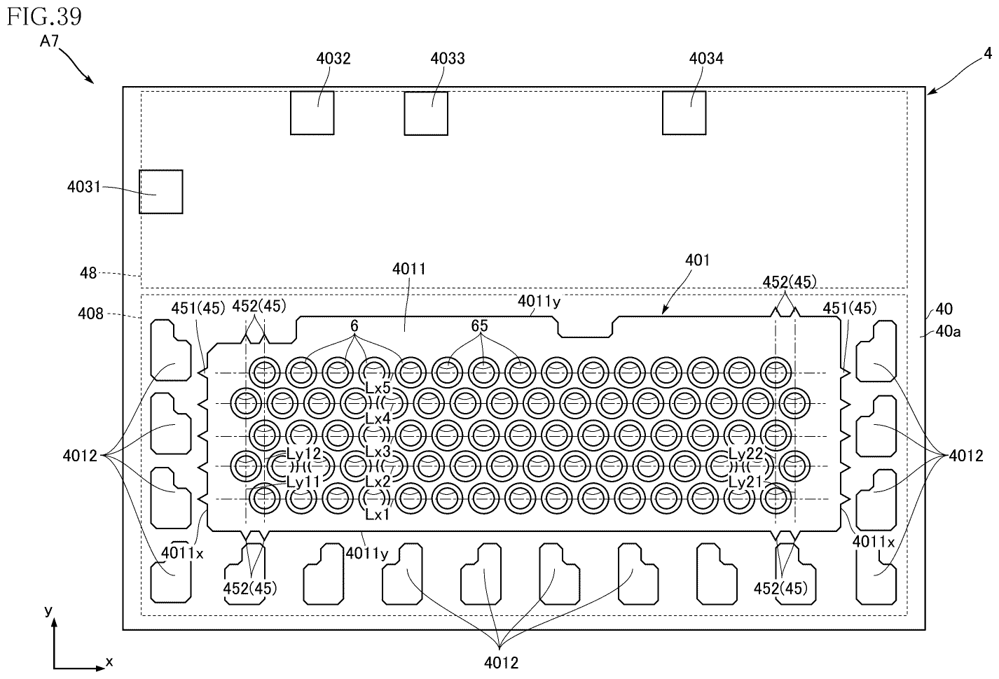

FIG. 39 shows a semiconductor element 4 of a semiconductor device according to a seventh embodiment of the present disclosure. The semiconductor device A7 of the present embodiment includes the semiconductor element 4 having positioning reference portions 45 different from those of the foregoing embodiments. In the present embodiment, each of the two first edges 4011x of the first region 4011 has a plurality of portions that are bent outward as viewed in the z direction. These portions form the first positioning reference portions 451. Each of the two second edges 4011y of the first region 4011 has a plurality of portions that are bent outward as viewed in the z direction. These portions form the second positioning reference portions 452. The positioning reference portions 45 shown in the figure each have a triangular shape with a vertex pointing outward but this is not a limitation. Various shapes, including those shown in FIG. 36, may be used for the positioning reference portions 45.

The present embodiment enables active clamping to function more effectively. The positioning reference portions 45 of this embodiment require less space, facilitating a decrease in the size of the semiconductor element 4.

Eighth Embodiment

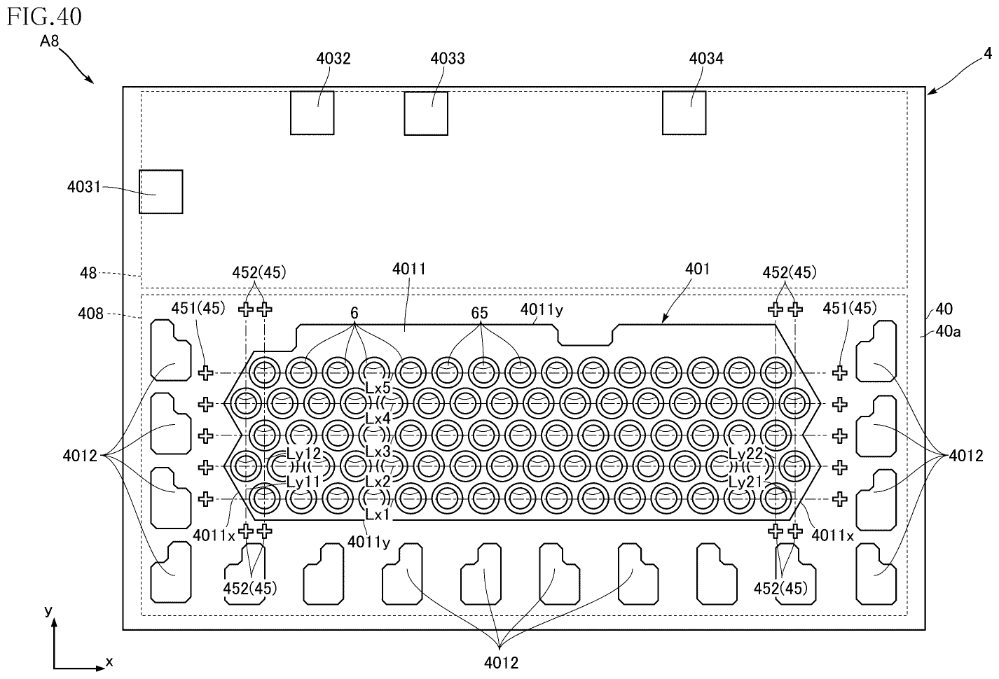

FIG. 40 shows a semiconductor element 4 of a semiconductor device according to an eighth embodiment of the present disclosure. The semiconductor device A8 of the present embodiment includes the semiconductor element 4 having a first region 4011 different from that of the foregoing embodiments. In the present embodiment, the first region 4011 has two first edges 4011x with a bent shape. Specifically, each first edge 4011x contains a plurality of segments each inclined relative to the x direction and the y direction. Each of these segments is arranged and inclined to follow the staggered arrangement of the metal bumps 6.

The present embodiment enables active clamping to function more effectively. According to the present embodiment, the size of the first region 4011 can be reduced, facilitating a decrease in the size of the semiconductor element 4.

### First Variation of Eighth Embodiment

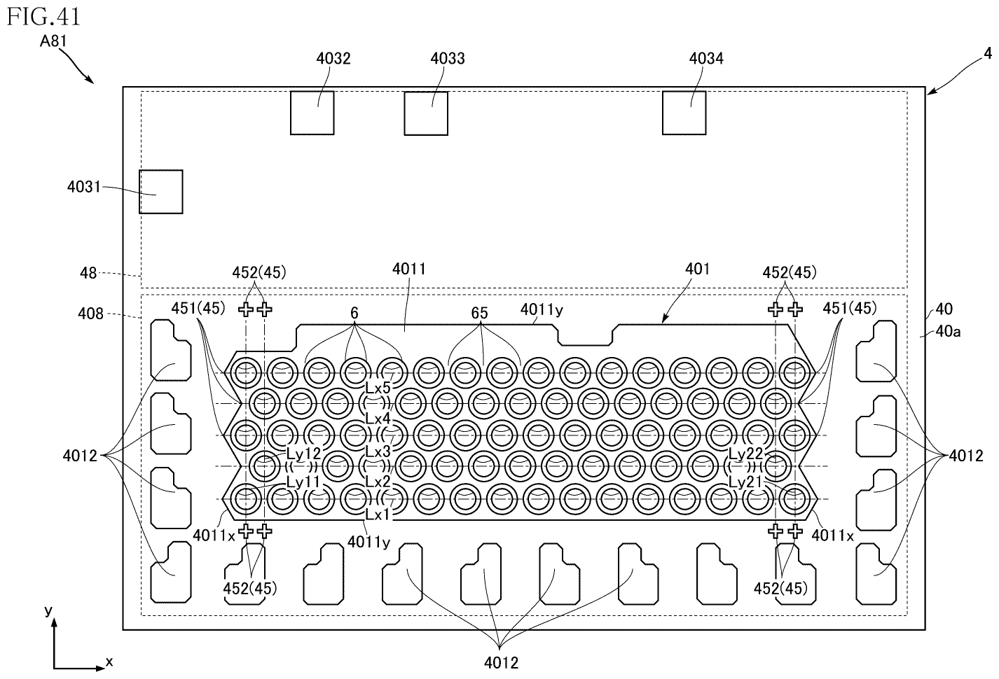

FIG. 41 shows a first variation of the semiconductor device A8. The semiconductor device A81 of this variation differs from the foregoing embodiments in the configuration of the first region 4011 of the semiconductor element 4 and the positioning reference portions 45. In this variation, the first edges 4011x include consecutive inclined segments, forming first positioning reference portions 451 at their junctions. Each junction includes one segment inclined inward of the first region 4011 and one segment inclined outward of the first region 4011. These portions with such a geometric shape form the first positioning reference portions 451.

This variation enables active clamping to function more effectively. According to this variation, the size of the first region 4011 can be reduced, and no dedicated space is required for placing the first positioning reference portions 451. This further facilitates a decrease in the size of the semiconductor element 4.

### Ninth Embodiment

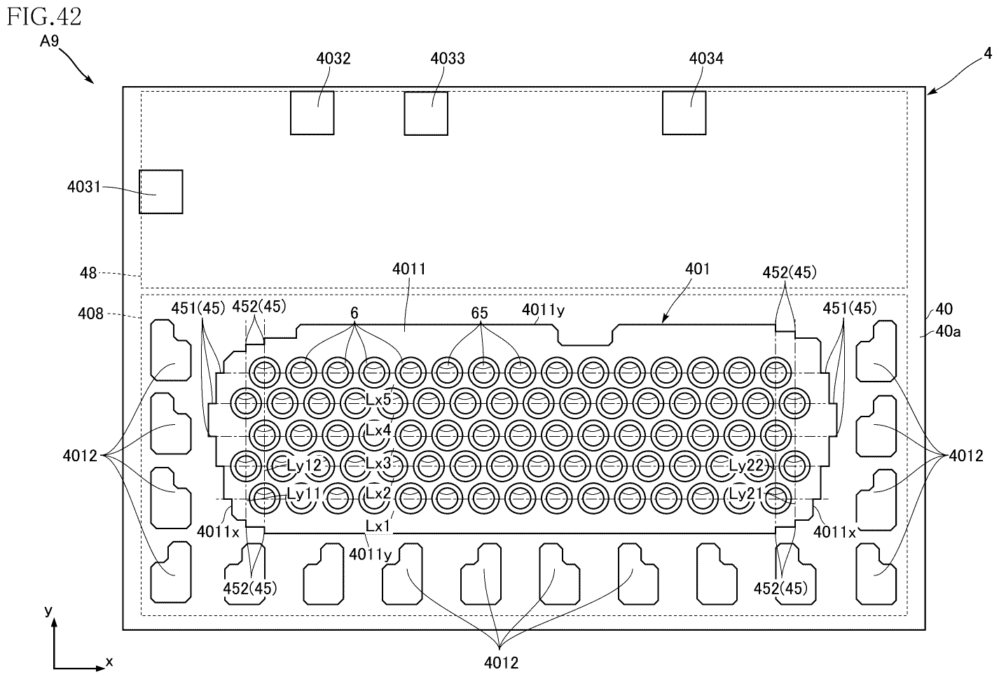

FIG. 42 shows a semiconductor element 4 of a semiconductor device according to a ninth embodiment of the present disclosure. The semiconductor device A9 of the present embodiment differs from the foregoing embodiments in the configuration of the first region 4011 of the semiconductor element 4 and the positioning reference portions 45. In the present embodiment, the two first edges 4011x and the two second edges 4011y each have a plurality of stepped portions. These stepped portions form the first positioning reference portions 451 and the second positioning reference portions 452. Each first edge 4011x has a plurality of stepped portions, such that each stepped portion that is closer to the center in the y direction is longer in the x direction than the others.

The present embodiment enables active clamping to function more effectively. According to the present embodiment, no dedicated space is required either for placing the first positioning reference portions 451 or for placing the second positioning reference portions 452. This further facilitates a decrease in the size of the semiconductor element 4.

### First Variation of Ninth Embodiment

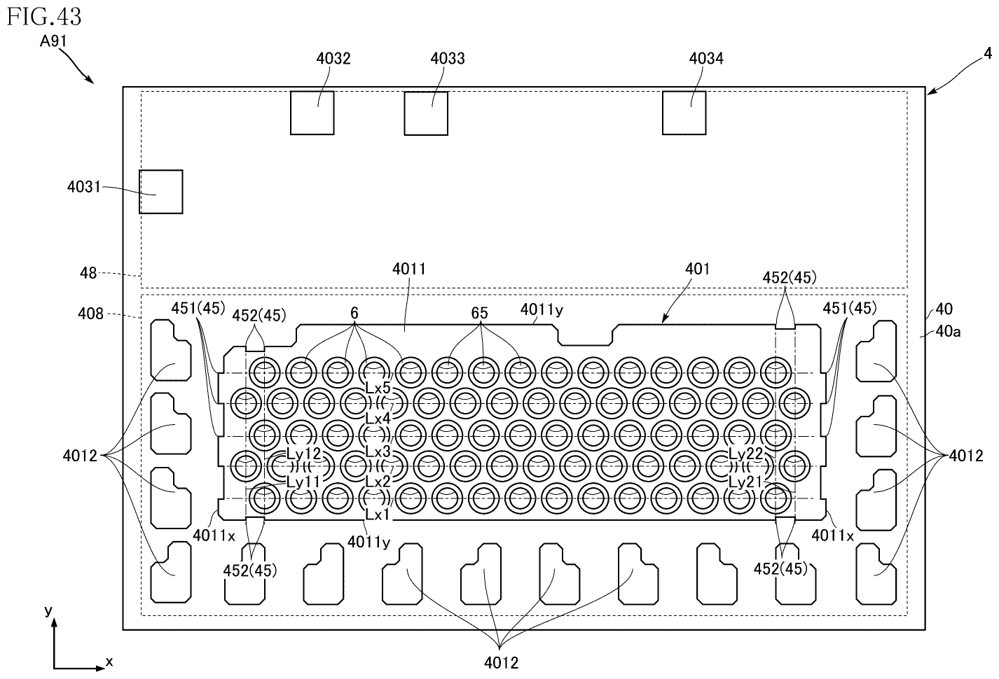

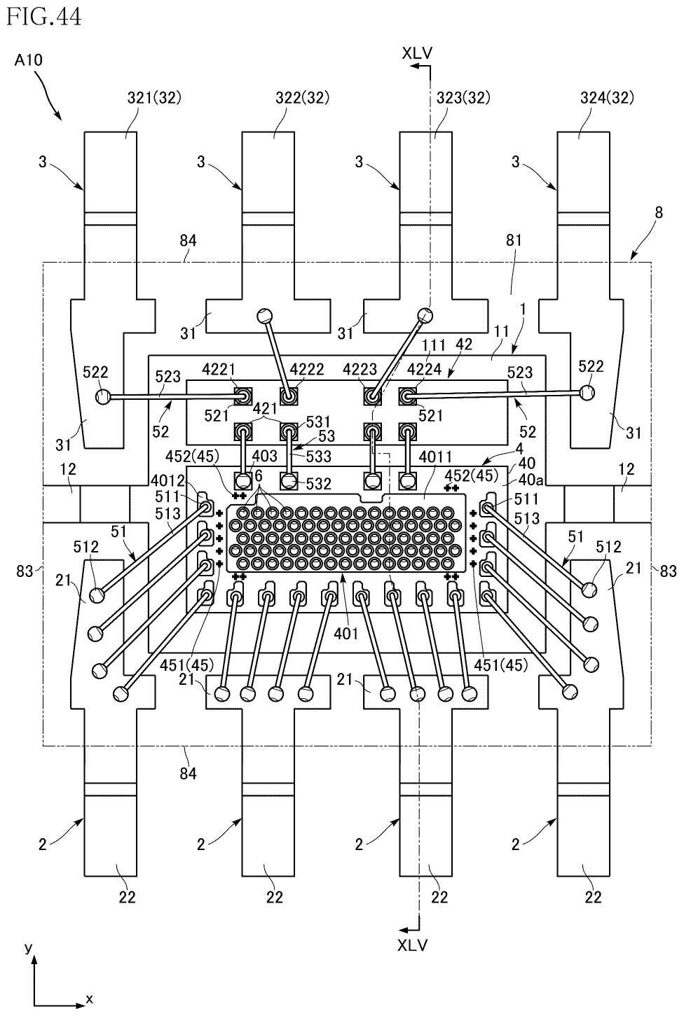

FIG. 43 shows the semiconductor clement 4 of a first variation of the semiconductor device A9. The semiconductor device A91 of this variation differs from the foregoing embodiments in the configuration of the first region 4011 of the semiconductor clement 4 and the positioning reference portions 45. In the present embodiment, the two first edges 4011x and the two second edges 4011y each have a rectangular recess and thus has a stepped portion on either side of the recess. The stepped portions on the sides of these recesses form the first positioning reference portions 451 and the second positioning reference portions 452.

The present embodiment enables active clamping to function more effectively. In this variation, the length of the first region 4011 in the x direction vary to some extent due to the presence of the stepped portions. Unlike the configuration shown in FIG. 42, however, the first region 4011 is not particularly longer around the central portion in the y direction. This variation is thus preferable for reducing the size of the semiconductor clement 4.

### Tenth Embodiment

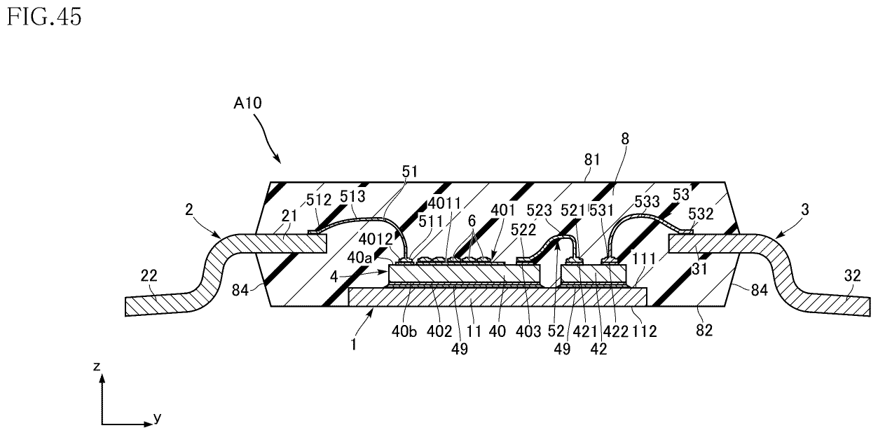

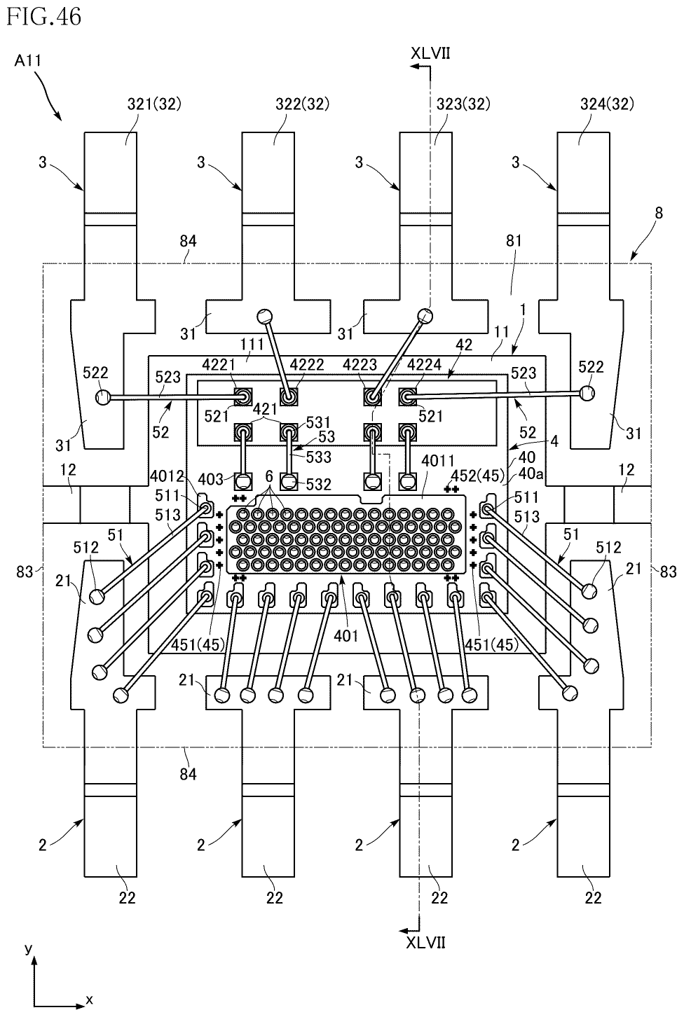

FIGS. 44 and 45 show a semiconductor device according to a tenth embodiment of the present disclosure. The semiconductor device A10 of the present embodiment differs from the above-described embodiments in the configuration of the semiconductor clement 4 and in the addition of a semiconductor clement 42 and a plurality of third wires 53.

The semiconductor element 4 of the present embodiment includes the switching section 408 described in the foregoing embodiments to implement the switching function but does not include the control section 48 described in the foregoing embodiments.

The semiconductor clement 42 has the function of controlling, monitoring, and protecting the semiconductor element 4, for example. The semiconductor elements 4 and 42 are both attached to the die pad obverse surface 111 of the die pad portion 11 via a bonding material 49. In the illustrated example, the semiconductor elements 4 and 42 are arranged in the y direction.

The semiconductor element 42 includes a plurality of electrodes 421 and a plurality of electrodes 422. All of the electrodes 421 and 422 are disposed on the same side in the z direction. In the illustrated example, the electrodes 421 are located closer to the semiconductor element 4 in the y direction, and the electrodes 422 are located closer to the third leads 3 in the y direction. The plurality of electrodes 422 include electrodes 4221, 4222, 4223, and 4224. The electrodes 4221 corresponds to the third electrode 4031 of the semiconductor device A1 described above. The electrodes 4222 corresponds to the third electrode 4032 of the semiconductor device A1 described above. The electrodes 4223 corresponds to the third electrode 4033 of the semiconductor device A1 described above. The electrodes 4224 corresponds to the third electrode 4034 of the semiconductor device A1 described above.

In the present embodiment, each of the second wires 52 is connected to an electrode 422 of the semiconductor element 42 and a third lead 3. The bonding portion 521 is bonded to the electrode 422, whereas the bonding portion 522 is bonded to the pad portion 31 of the third lead 3.

The semiconductor device A10 includes a plurality of third wires 53. Each of the third wires 53 is connected to a third electrode 403 of the semiconductor element 4 and an electrode 421 of the semiconductor clement 42. Each third wire 53 includes bonding portion 531 and 532 and a loop portion 533, similarly to the second wire 52. The bonding portion 531 is bonded to the third electrode 403. The bonding portion 532 is bonded to the electrodes 421.

The present embodiment enables active clamping to function more effectively. As can be understood from the present embodiment, the configuration of the semiconductor element 4 is not specifically limited. In addition to the semiconductor element 4, one or more other semiconductor elements, such as the semiconductor element 42, may be attached to the die pad portion 11. The functions of the semiconductor elements other than the semiconductor element 4 are not specifically limited.

### Eleventh Embodiment

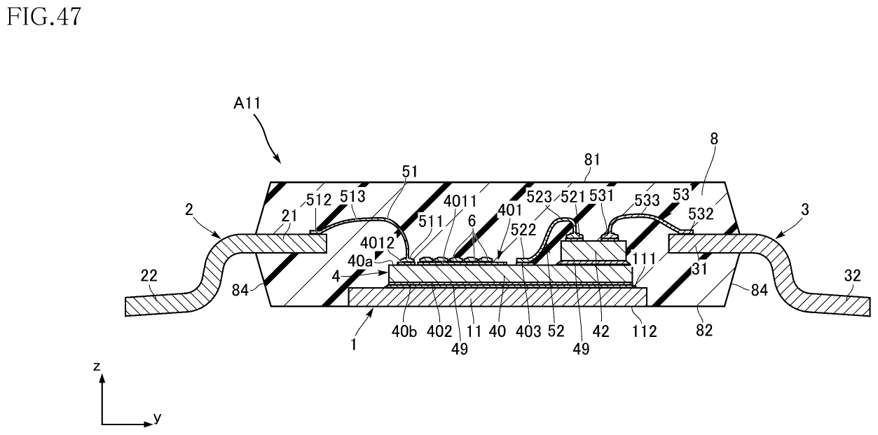

FIGS. 46 and 47 show a semiconductor device according to an eleventh embodiment of the present disclosure. Similarly to the semiconductor device A10, the semiconductor device A11 of the present embodiment includes semiconductor elements 4 and 42.

In the present embodiment, the semiconductor element 42 is mounted on the element obverse surface 40a of the semiconductor element 4. That is, the semiconductor element 42 is on the opposite side of the semiconductor element 4 from the die pad portion 11 in the z direction. The semiconductor element 4 and the semiconductor clement 42 are stacked one on top of the other.

The semiconductor element 42 is bonded to the element obverse surface 40a of the semiconductor element 4 via a bonding material 49, for example. In the illustrated example, the semiconductor element 42 is away from the first electrode 401 in the y direction as viewed in the z direction. In a different example, the semiconductor element 42 may be disposed on the first electrode 401.

In the illustrated example, the first electrode 401 and the semiconductor element 42 both have a rectangle shape elongated in the x direction. The third electrodes 403 are located between the first electrode 401 and the semiconductor element 42 in the y direction and arranged in the x direction.

The present embodiment enables active clamping to function more effectively. As can be understood from the present embodiment, the configuration and the details of the mounting of the semiconductor element 42 are not specifically limited.

The semiconductor device and the method for manufacturing the semiconductor device of the present disclosure are not limited to those of the foregoing embodiments. Various design changes may be made freely in the specific configurations of the semiconductor device and of the manufacturing methods of the present disclosure.

The present disclosure include embodiments described in the following clauses.

### Clause 1A

A semiconductor device comprising:
a semiconductor element including a first electrode; and
at least one metal bump bonded to the first electrode,
wherein the metal bump includes a fractured portion located on a first side in a thickness direction of the semiconductor element, the first side being farther from the first electrode, and
as viewed in the thickness direction, a center of the fractured portion is offset from a center of the metal bump.

### Clause 2A

The semiconductor device according to Clause 1A, wherein as viewed in the thickness direction, a whole of the fractured portion is spaced apart from the center of the metal bump.

### Clause 3A

The semiconductor device according to Clause 1A or 2A, wherein the metal bump includes a large-diameter portion in contact with the first electrode, and a small-diameter portion located on a side of the large-diameter portion opposite the first electrode, the small-diameter portion having a diameter smaller than that of the large-diameter portion.

### Clause 4A

The semiconductor device according to Clause 3A, wherein as viewed in the thickness direction, a center of the large-diameter portion and a center of the small-diameter portion both coincide with the center of the metal bump.

### Clause 5A

The semiconductor device according to Clause 3A or 4A, wherein the metal bump includes a first tapered portion between the large-diameter portion and the small-diameter portion.

### Clause 6A

The semiconductor device according to any one of Clauses 1A to 3A, wherein the metal bump includes a top surface located on the first side in the thickness direction, the top surface being adjacent to the fractured portion as viewed in the thickness direction.

### Clause 7A

The semiconductor device according to Clause 6A, wherein as viewed in the thickness direction, the top surface is larger than the fractured portion.

### Clause 8A

The semiconductor device according to any one of Clauses 1A to 7A, wherein the at least one metal bump comprises a plurality of metal bumps, and
for the plurality of metal bumps, the centers of the fractured portions are offset from the centers of the metal bumps in a same direction.

### Clause 9A

The semiconductor device according to Clause 8A, wherein the plurality of metal bumps are arranged in a plurality of lines in a first direction perpendicular to the thickness direction, and
for each of the plurality of metal bumps, the center of the fractured portion is offset from the center of the metal bump in a second direction intersecting the first direction.

### Clause 10A

The semiconductor device according to any one of Clauses 1A to 7A, further comprising a wire connected to the first electrode.

### Clause 11A

The semiconductor device according to Clause 10A, wherein the first electrode includes a first region where the metal bump is located, and a second region where the wire is connected.

### Clause 12A

A method for manufacturing a semiconductor device, the method comprising:
passing a wire material including a main body with a uniform diameter through a through-hole in a capillary and forming a ball at a tip of the wire material;
attaching the ball to a first electrode of a semiconductor element;
moving the capillary away from the first electrode in a thickness direction of the semiconductor element while allowing relative movement between the capillary and the wire material;
sliding the capillary in a sliding direction intersecting the thickness direction; and
moving the capillary toward the first side in the thickness direction while preventing relative movement between the capillary and the wire material, thereby causing the wire material to break and forming a metal bump bonded to the first electrode.

### Clause 13A

The method according to Clause 12A, wherein the sliding of the capillary includes sliding the capillary until a whole of a tip portion of the capillary is positioned away from a center of the metal bump as viewed in the thickness direction.

### Clause 14A

The method according to Clause 12A or 13A, wherein the attaching of the ball includes forming a large-diameter portion and a small-diameter portion, the large-diameter portion being a portion of the ball that is located between the capillary and the first electrode, the small-diameter portion being a portion of the ball that enters the through-hole.

### Clause 15A

The method according to Clause 14A, wherein the moving of the capillary away from the first electrode includes moving the capillary until a tip portion of the capillary overlaps with the small-diameter portion as viewed in a direction perpendicular to the thickness direction.

### Clause 16A

The method according to Clause 15A, wherein the through-hole includes a tapered portion leading to the tip portion, and
the forming of the ball includes forming a first tapered portion between the large-diameter portion and the small-diameter portion, the first tapered portion being a portion of the ball in contact with the tapered portion.

### Clause 17A

The method according to Clause 16A, wherein the moving of the capillary away from the first electrode includes moving the capillary until the tip portion of the capillary is positioned beyond the first tapered portion of the through-hole.

### Clause 18A

The method according to any one of Clauses 12A to 17A, wherein in the sliding of the capillary, the sliding direction is perpendicular to the thickness direction.

### Clause 1B

A semiconductor device comprising:
a semiconductor element including a first electrode;
a plurality of metal bumps bonded to the first electrode; and
at least one positioning reference portion that serves as a positioning reference for the plurality of metal bumps.

### Clause 2B

The semiconductor device according to Clause 1B, further comprising:
a metal layer; and
an insulating film that covers a portion of the metal layer,
wherein the first electrode is a portion of the metal layer that is exposed from the insulating film.

### Clause 3B

The semiconductor device according to Clause 2B, wherein the positioning reference portion is a portion of the metal layer that is exposed from the insulating film.

### Clause 4B

The semiconductor device according to any one of Clauses 1B to 3B, wherein the positioning reference portion is spaced apart from the first electrode in plan view.

### Clause 5B

The semiconductor device according to any one of Clauses 1B to 3B, wherein the positioning reference portion is formed by a portion of an edge of the first electrode.

### Clause 6B

The semiconductor device according to Clause 5B, wherein the positioning reference portion is formed by an inwardly bent portion of the edge of the first electrode in plan view.

### Clause 7B

The semiconductor device according to Clause 5B, wherein the positioning reference portion is formed by an outwardly bent portion of the edge of the first electrode in plan view.

### Clause 8B

The semiconductor device according to Clause 5B, wherein the positioning reference portion is formed by a stepped portion of the edge of the first electrode in plan view.

### Clause 9B

The semiconductor device according to any one of Clauses 1B to 8B, wherein the at least one positioning reference portion comprises a plurality of positioning reference portions.

### Clause 10B

The semiconductor device according to Clause 9B, wherein the plurality of metal bumps are arranged in the first direction in plan view, and
the plurality of positioning reference portions include a first positioning reference portion that serves as a positioning reference for the plurality of metal bumps arranged in the first direction.

### Clause 11B

The semiconductor device according to Clause 10B, wherein the plurality of metal bumps are arranged in a plurality of lines in the first direction in plan view,
the plurality of metal bumps arranged in the plurality of lines in the first direction are also arranged in a plurality of lines in a second direction that intersects the first direction in plan view, and
the plurality of positioning reference portions include a second positioning reference portion that serves as a positioning reference for the plurality of metal bumps arranged in the second direction.

### Clause 12B

The semiconductor device according to Clause 11B, wherein the plurality of positioning reference portions include a plurality of first positioning reference portions that are equal in number to the plurality of lines of the plurality of metal bumps in the first direction.

### Clause 13B

The semiconductor device according to Clause 12B, wherein the plurality of positioning reference portions include a plurality of second positioning reference portions that are fewer in number than the plurality of lines of the plurality of metal bumps in the second direction.

### Clause 14B

The semiconductor device according to Clause 13B, wherein each of the plurality of second positioning reference portions is located at a position corresponding to an outermost one of the plurality of metal bumps arranged in the first direction.

### Clause 15B

The semiconductor device according to any one of Clauses 11B to 14B, wherein each of the plurality of metal bumps includes a fractured portion on a first side in a thickness direction of the semiconductor element, the first side being farther from the first electrode, and
for each of the plurality of metal bumps, a center of the fractured portion is offset from a center of the metal bump as viewed in the thickness direction.

### Clause 16B

The semiconductor device according to Clause 15B, wherein for each of the plurality of metal bumps, the center of the fractured portion is offset from the center of the metal bump in the second direction.

### Clause 17B

The semiconductor device according to any one of Clauses 1B to 16B, further comprising: a wire connected to the first electrode.

### REFERENCE NUMERALS

A1, A2, A3, A4: semiconductor device A5, A51, A6, A7, A8, A81: semiconductor device A9, A91, A10, A11: semiconductor device 1: first lead 2: second lead 3: third lead 4: semiconductor element 6: metal bump 8: sealing resin 11: die pad portion 12: extending portion 21: pad portion 22: terminal portion 31: pad portion 32: terminal portion 40: element body 40a: element obverse surface 40b: element reverse surface 42: semiconductor element 45: positioning reference portion 46: insulating film 48: control section 49: bonding material 51: first wire 52: second wire 53: third wire 60: main body 61: large-diameter portion 62: small-diameter portion 63: first tapered portion 64: top surface 65: fractured portion 66: second tapered portion 67: constricted portion 69: ball 81: resin obverse surface 82: resin reverse surface 83: first resin side surface 84: second resin side surface 91: through-hole 92: tip portion 111: die pad obverse surface 112: die pad reverse surface 321, 322, 323, 324: terminal portion 401: first electrode 402: second electrode 403: third electrode 408: switching section 421, 422: electrode 451: first positioning reference portion 452: second positioning reference portion 461: opening 481: energy absorption circuit 482: protection circuit 511, 512, 521, 522, 531, 532: bonding portion 513, 523, 533: loop portion 911: uniform-diameter portion 912: tapered portion 4010: metal layer 4011: first region 4011x: first edge 4011y: second edge 4012: second region 4031, 4032, 4033, 4034: third electrode 4221, 4222, 4223, 4224: electrode 4821: heat protection section 4822: overcurrent protection section Cp: capillary Lx1, Lx2, Lx3, Lx4, Lx5: reference line Ly11, Ly12, Ly21, Ly22: reference line O1, O2: center W: wire material

1. A semiconductor device comprising:
a semiconductor element including a first electrode; and
at least one metal bump bonded to the first electrode,
wherein the metal bump includes a fractured portion located on a first side in a thickness direction of the semiconductor element, the first side being farther from the first electrode, and
as viewed in the thickness direction, a center of the fractured portion is offset from a center of the metal bump.

2. The semiconductor device according to claim 1, wherein as viewed in the thickness direction, a whole of the fractured portion is spaced apart from the center of the metal bump.

3. The semiconductor device according to claim 1, wherein the metal bump includes a large-diameter portion in contact with the first electrode, and a small-diameter portion located on a side of the large-diameter portion opposite the first electrode, the small-diameter portion having a diameter smaller than that of the large-diameter portion.

4. The semiconductor device according to claim 3, wherein as viewed in the thickness direction, a center of the large-diameter portion and a center of the small-diameter portion both coincide with the center of the metal bump.

5. The semiconductor device according to claim 3, wherein the metal bump includes a first tapered portion between the large-diameter portion and the small-diameter portion.

6. The semiconductor device according to claim 1, wherein the metal bump includes a top surface located on the first side in the thickness direction, the top surface being adjacent to the fractured portion as viewed in the thickness direction.

7. The semiconductor device according to claim 6, wherein as viewed in the thickness direction, the top surface is larger than the fractured portion.

8. The semiconductor device according to claim 1, wherein the at least one metal bump comprises a plurality of metal bumps, and
for the plurality of metal bumps, the centers of the fractured portions are offset from the centers of the metal bumps in a same direction.

9. The semiconductor device according to claim 8, wherein the plurality of metal bumps are arranged in a plurality of lines in a first direction perpendicular to the thickness direction, and
for each of the plurality of metal bumps, the center of the fractured portion is offset from the center of the metal bump in a second direction intersecting the first direction.

10. The semiconductor device according to claim 1, further comprising a wire connected to the first electrode.

11. The semiconductor device according to claim 10, wherein the first electrode includes a first region where the metal bump is located, and a second region where the wire is connected.

12. A method for manufacturing a semiconductor device, the method comprising:
passing a wire material including a main body with a uniform diameter through a through-hole in a capillary and forming a ball at a tip of the wire material;
attaching the ball to a first electrode of a semiconductor element;
moving the capillary away from the first electrode in a thickness direction of the semiconductor element while allowing relative movement between the capillary and the wire material;
sliding the capillary in a sliding direction intersecting the thickness direction; and
moving the capillary toward the first side in the thickness direction while preventing relative movement between the capillary and the wire material, thereby causing the wire material to break and forming a metal bump bonded to the first electrode.

13. The method according to claim 12, wherein the sliding of the capillary includes sliding the capillary until a whole of a tip portion of the capillary is positioned away from a center of the metal bump as viewed in the thickness direction.

14. The method according to claim 12, wherein the attaching of the ball includes forming a large-diameter portion and a small-diameter portion, the large-diameter portion being a portion of the ball that is located between the capillary and the first electrode, the small-diameter portion being a portion of the ball that enters the through-hole.

15. The method according to claim 14, wherein the moving of the capillary away from the first electrode includes moving the capillary until a tip portion of the capillary overlaps with the small-diameter portion as viewed in a direction perpendicular to the thickness direction.

16. The method according to claim 15, wherein the through-hole includes a tapered portion leading to the tip portion, and
the forming of the ball includes forming a first tapered portion between the large-diameter portion and the small-diameter portion, the first tapered portion being a portion of the ball in contact with the tapered portion of the through-hole.

17. The method according to claim 16, wherein the moving of the capillary away from the first electrode includes moving the capillary until the tip portion of the capillary is positioned beyond the first tapered portion.

18. The method according to claim 12, wherein in the sliding of the capillary, the sliding direction is perpendicular to the thickness direction.

19. A semiconductor device comprising:
a semiconductor element including a first electrode;
a plurality of metal bumps bonded to the first electrode; and
at least one positioning reference portion that serves as a positioning reference for the plurality of metal bumps.

20. The semiconductor device according to claim 19, further comprising:
a metal layer; and
an insulating film that covers a portion of the metal layer,
wherein the first electrode is a portion of the metal layer that is exposed from the insulating film.
